(19) United States
(12) Patent Application Publication
(10) Pub. No.: US 2026/0112402 A1
(43) Pub. Date: Apr. 23, 2026

(54) MEMORY SYSTEM RECEIVING HETEROGENEOUS POWER SOURCES AND ELECTRONIC APPARATUS INCLUDING THE SAME

(71) Applicant: SK hynix Inc., Gyeonggi-do (KR)

(72) Inventors: Young Sub YUK, Gyeonggi-do (KR); Seong Jin YUN, Gyeonggi-do (KR)

(21) Appl. No.: 19/172,649

(22) Filed: Apr. 8, 2025

(30) Foreign Application Priority Data
Oct. 23, 2024 (KR) 10-2024-0145791

(51) Int. Cl. G11C 11/4074; G11C 5/14; G11C 11/4096

(52) U.S. Cl. CPC G11C 11/4074; G11C 5/147; G11C 11/4096

(57) ABSTRACT

A memory system includes a memory device configured to operate by receiving, from an outside, a first power source having a first voltage level, and a controller configured to perform a control operation of controlling the memory device and to generate a control power source for the control operation by: receiving, from an outside, a second power source, which has a second voltage level lower than the first voltage level, when a present current amount of the control power source is equal to or less than a first current amount, and receiving both the first and second power sources when the present current amount exceeds the first current amount.

### CROSS-REFERENCE TO RELATED APPLICATION

This application claims priority under 35 U.S. C. § 119(a) to Korean Patent Application No. 10-2024-0145791, filed on Oct. 23, 2024, the entire contents of which are incorporated herein by reference.

### BACKGROUND

### 1. Field

Embodiments of the present disclosure relate to a semiconductor integrated device, and specifically, to a memory system that operates by receiving heterogeneous power sources and an electronic apparatus including the same.

### 2. Discussion of the Related Art

Memory systems are storage devices embodied using a semiconductor such as silicon (Si), germanium (Ge), gallium arsenide (GaAs), indium phosphide (InP), or the like. The memory systems are classified into a volatile memory device and a nonvolatile memory device. The volatile memory device is a memory device in which data stored therein is lost when power supply is interrupted. Representative examples of the volatile memory device include static RAM (SRAM), dynamic RAM (DRAM), synchronous DRAM (SDRAM), etc. The nonvolatile memory device is a memory device in which data stored therein is retained even when power supply is interrupted. Representative examples of the nonvolatile memory device include a read only memory (ROM), a programmable ROM (PROM), an electrically programmable ROM (EPROM), an electrically erasable programmable ROM (EEPROM), a flash memory, a phase-change random access memory (PRAM), a magnetic RAM (MRAM), a resistive RAM (RRAM), a ferroelectric RAM (FRAM), etc. Flash memories are chiefly classified into a NOR-type memory and NAND-type memory.

Data storage devices using nonvolatile memory devices have advantages such as excellent stability and durability, very high information access speed, and low power consumption, unlike hard disks, because the data storage devices do not have mechanical drive units. Examples of a memory system having such advantages, are a data storage device that includes a universal aerial bus (USB) memory device, a memory card having various interfaces, a solid state drive (SSD), and the like.

Electronic apparatuses for the purpose of storing data, such as memory systems, include memory devices for storing data and controllers for controlling operations such as write, read, and erase, of the memory devices.

In addition, a power source used by the memory device and a power source used by the controller may be managed in a physically separate form. For example, the memory device may operate by receiving a first power source of 2.5 V level and maximum 2000 mA, and the controller may operate by receiving a second power source of 1.2 V level and maximum 2000 mA.

As the usage of electronic apparatuses such as memory systems expands, the types of operations required by the memory systems are increasing more than before, and the operation method is becoming more complex than before, and thus, the amount of current used by the controller within the memory system is also increasing significantly.

However, since the second power source supplied to the controller has a preset maximum available current amount, for example, a current amount of 2000 mA, when current exceeding the maximum current amount is used while the controller is performing operations, problems such as abnormal operation or operation stop of the entire memory system may occur.

### SUMMARY

Various embodiments of the present disclosure are directed to providing a controller that operates by receiving the heterogeneous power sources and an electronic apparatus such as a memory system including a memory device in which the controller can determine a current operation state by itself and operate by selectively receiving the heterogeneous power sources according to the determination result.

Technical problems to be solved by the present disclosure are not limited to the aforementioned technical problems and other unmentioned technical problems that may occur will be clearly understood by those skilled in the art from the following description.

In an embodiment of the present disclosure, a memory system may include a memory device configured to operate by receiving, from an outside, a first power source having a first voltage level; and a controller configured to perform a control operation of controlling the memory device and to generate a control power source for the control operation by: receiving, from an outside, a second power source, which has a second voltage level lower than the first voltage level, when a present current amount of the control power source is equal to or less than a first current amount, and receiving both the first and second power sources when the present current amount exceeds the first current amount.

In an embodiment of the present disclosure, an electronic apparatus may include
a power generation device configured to generate, by using an external power source, a first power source having a first voltage level and a second power source having a second voltage level lower than the first voltage level; a slave device configured to perform an internal operation by receiving the first power source; and a master device configured to perform a control operation of controlling the slave device and to generate a control power source for the control operation by: receiving, from an outside, the second power source when a present current amount of the control power source is equal to or less than a first current amount, and receiving both the first and second power sources when the present current amount exceeds the first current amount.

According to the present disclosure, in a controller that operates by receiving the heterogeneous power sources and an electronic apparatus such as a memory system including a memory device, the controller can control operations by selectively using all heterogeneous power sources according to a result of confirming by itself an amount of current currently being used.

This can prevent the occurrence of a phenomenon such as an abnormal operation or operation stop of an electronic apparatus such as a memory system including a controller due to insufficient current.

### BRIEF DESCRIPTION OF THE DRAWINGS

FIGS. 1A and 1B are diagrams for describing a data processing system including a memory system in accordance with a first embodiment of the present disclosure.

FIGS. 2A and 2B are diagrams for describing a controller included in the memory system in accordance with the first embodiment of the present disclosure.

FIGS. 3A to 3C are diagrams for describing an operation in which the controller in accordance with the first embodiment of the present disclosure generates a control power source.

FIGS. 4A to 4C are diagrams for describing an operation in which a power supply section included in the controller in accordance with the first embodiment of the present disclosure supplies current.

FIG. 5 is a diagram for describing a detailed configuration of a supply control part among components of the power supply section included in the controller in accordance with the first embodiment of the present disclosure.

FIGS. 6A and 6B are diagrams for describing a detailed configuration of a current supply part among the components of the power supply section included in the controller in accordance with the first embodiment of the present disclosure.

FIG. 7 is a diagram for describing an electronic apparatus including a master device and a slave device in accordance with a second embodiment of the present disclosure.

FIGS. 8A to 8C are diagrams for describing an operation in which the master device in accordance with the second embodiment of the present disclosure generates a control power source.

FIGS. 9A to 9C are diagrams for describing an operation in which a power supply section included in the master device in accordance with the second embodiment of the present disclosure supplies current.

FIG. 10 is a diagram for describing a detailed configuration of a supply control part among components of the power supply section included in the master device in accordance with the second embodiment of the present disclosure.

FIGS. 11A and 11B are diagrams for describing a detailed configuration of a current supply part among the components of the power supply section included in the master device in accordance with the second embodiment of the present disclosure.

### DETAILED DESCRIPTION

Various embodiments of the present disclosure are described below with reference to the accompanying drawings. Elements and features of the disclosure, however, may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components (e.g., an interface unit, circuitry, etc.).

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational (e.g., is not turned on nor activated). The block/unit/circuit/component used with the “configured to” language includes hardware-for example, circuits, memory storing program instructions executable to implement the operation, etc. Additionally, “configured to” can include a generic structure (e.g., generic circuitry) that is manipulated by software and/or firmware (e.g., an FPGA or a general-purpose processor executing software) to operate in a manner that is capable of performing the task(s) at issue. “Configured to” may also include adapting a manufacturing process (e.g., a semiconductor fabrication facility) to fabricate devices (e.g., integrated circuits) that implement or perform one or more tasks.

As used in the disclosure, the term ‘circuitry’ or ‘logic’ refers to all of the following: (a) hardware-only circuit implementations (such as implementations in only analog and/or digital circuitry) and (b) combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘circuitry’ or ‘logic’ applies to all uses of this term in this application, including in any claims. As a further example, as used in this application, the term “circuitry” or “logic” also covers an implementation of merely a processor (or multiple processors) or a portion of a processor and its (or their) accompanying software and/or firmware. The term “circuitry” or “logic” also covers, for example, and if applicable to a particular claim element, an integrated circuit for a storage device.

As used herein, the terms “first,” “second,” “third,” and so on are used as labels for nouns that the terms precede, and do not imply any type of ordering (e.g., spatial, temporal, logical, etc.). The terms “first” and “second” do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term “based on” is used to describe one or more factors that affect a determination. This term does not foreclose additional factors that may affect a determination. That is, a determination may be solely based on those factors or based, at least in part, on those factors. For example, the phrase “determine A based on B.” While in this case, B is a factor that affects the determination of A, such a phrase does not foreclose the determination of A from also being based on C. In other instances, A may be determined based solely on B.

Herein, an item of data, a data item, a data entry or an entry of data may be a sequence of bits. For example, the data item may include the contents of a file, a portion of the file, a page in memory, an object in an object-oriented program, a digital message, a digital scanned image, a part of a video or audio signal, metadata or any other entity which can be represented by a sequence of bits. According to an embodiment, the data item may include a discrete object. According to another embodiment, the data item may include a unit of information within a transmission packet between two different components.

### First Embodiment

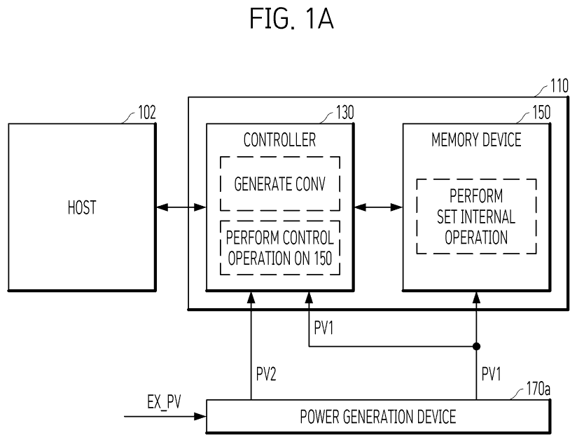

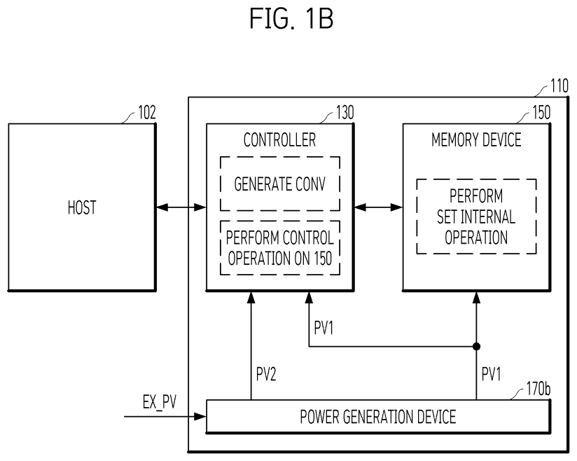

FIGS. 1A and 1B are diagrams for describing a data processing system including a memory system in accordance with a first embodiment of the present disclosure.

Referring to FIGS. 1A and 1B, the data processing system may include a host 102 engaged or coupled with a memory system, such as memory system 110. For example, the host 102 and the memory system 110 can be coupled to each other via a data bus, a host cable and the like to perform data communication.

The memory system 110 may include a memory device 150 and a controller 130. The memory device 150 and the controller 130 in the memory system 110 may be considered components or elements physically separated from each other. The memory device 150 and the controller 130 may be connected via at least one data path. For example, the data path may include a channel and/or a way.

According to an embodiment, the memory device 150 and the controller 130 may be components or elements functionally divided. Further, according to an embodiment, the memory device 150 and the controller 130 may be implemented with a single chip or a plurality of chips. The controller 130 may perform a data input/output operation in response to a request input from the external device. For example, when the controller 130 performs a read operation in response to a read request input from an external device, data stored in a plurality of non-volatile memory cells included in the memory device 150 is transferred to the controller 130.

The controller 130 may control the memory device 150 to perform read, program and erase operations corresponding to commands inputted from the host 102, and the memory system 110 may independently perform the operations regardless of commands inputted from an external device such as the host 102.

In an embodiment, the controller 130 may autonomously generate a command, an address, and data regardless of a request from the host 102, and may transmit the command, the address, and the data to the memory device 150. For example, the controller 130 may provide commands, addresses, and data to the memory device 150 to perform background operations, such as a read operation and a program operation for wear leveling, garbage collection, read reclaim, and media scan.

The power generation device 170a or 170b generates power PV1 and PV2 used for the operation of the memory system 110. The power generation device 170a or 170b is provided outside the memory system 110 as illustrated in FIG. 1A, or is included inside the memory system 110 as illustrated in FIG. 1B.

In addition, the power generation device 170a or 170b receives an external power source EX_PV and generates a first power source PV1 having a first voltage level and a second power source PV2 having a second voltage level lower than the first voltage level. According to an embodiment, the first voltage level is a 2.5 V level, and the second voltage level is a 1.2 V level.

In addition, the power generation device 170a or 170b sets the maximum current amount of the first power source PV1 and the maximum current amount of the second power source PV2, respectively. According to an embodiment, the maximum current amount of the first power source PV1 is 2000 mA, and the maximum current amount of the second power source PV2 is 2000 mA.

Specifically, the memory device 150 operates a set internal operation by using the first power source PV1 supplied from the power generation device 170a or 170b. That is, to perform the set internal operation such as read, program, and erase under the control of the controller 130, the memory device 150 uses the first power source PV1 supplied from the power generation device 170a or 170b.

The controller 130 performs a control operation for controlling the set internal operation performed in the memory device 150. In addition, the controller 130 uses internally generated control power source CONV to perform the control operation.

When the present current amount of the internally generated control power source CONV is equal to or less than a first current amount, the controller 130 receives the second power source PV2 generated by the power generation device 170a or 170b to generate the control power source CONV, and then performs the control operation by using the generated control power source CONV. That is, when the present current amount of the control power source CONV is equal to or less than the first current amount, the controller 130 generates the control power source CONV by using only the current supplied from the second power source PV2.

When the present current amount of the internally generated control power source CONV exceeds the first current amount, the controller 130 simultaneously receives the first power source PV1 and the second power source PV2 generated by the power generation device 170a or 170b to generate the control power source CONV, and then performs the control operation by using the generated control power source CONV. That is, when the present current amount of the control power source CONV exceeds the first current amount, the controller 130 not only generates the control power source CONV by using the current supplied from the second power source PV2 but also supplies current to the control power source CONV by using the current supplied from the first power source PV1 at the same time.

In such a case, the controller 130 predefines the maximum amount of current suppliable from the first power source PV1 to the control power source CONV. That is, since the memory device 150 receives the first power source PV1 and performs a set internal operation, the controller 130 defines the maximum amount of current suppliable from the first power source PV1 to the control power source CONV as an amount that does not affect the set internal operation performed in the memory device 150. For example, the maximum amount of current of the first power source PV1 is 2000 mA and the amount that does not affect the set internal operation performed in the memory device 150 is 1700 mA. Accordingly, the controller 130 defines the maximum amount of current suppliable from the first power source PV1 to the control power source CONV as an amount of 300 mA.

The voltage level of the control power source CONV has a voltage level lower than the second voltage level, for example, a 0.75 V level.

The control operation performed by the controller 130 includes a plurality of sub-control operations.

For example, when the control operation performed by the controller 130 is an operation for controlling a program operation of the memory device 150, the plurality of sub-control operations may include an operation for transmitting a program command, program data, and an address by referring to mapping information, an operation for setting a program voltage level, an operation for transmitting program data, an operation for checking whether the program operation is successful, and the like.

For another example, when the control operation performed by the controller 130 is an operation for controlling a read operation of the memory device 150, the plurality of sub-control operations may include an operation for searching and transmitting a read address through mapping information, an operation for setting a read voltage level, an operation for correcting an error occurring in read data, an operation for outputting read data to the host, and the like.

The control operation performed by the controller 130 includes various other types of operations in addition to the program operation and read operation illustrated, and this is adjusted in various ways depending on the type of memory device and the designer's selection.

When the present current amount of the internally generated control power source CONV is equal to or greater than a second current amount greater than the first current amount, the controller 130 reduces the present current amount of the control power source CONV by stopping a M number of sub-control operations among a N number of sub-control operations being performed or scheduled to be performed, the control operation including the N number of sub-control operations. Here, N is a natural number equal to or greater than 1, and M is a natural number equal to or greater than 1 and equal to or less than N.

In such a case, the controller 130 adjusts the value of M so that the present current amount of the control power source CONV is equal to or less than the first current amount by stopping the M number of sub-control operations among the N number of sub-control operations being performed or scheduled to be performed, the control operation including the N number of sub-control operations.

According to an embodiment, in a case where the present current amount of the internally generated control power source CONV is equal to or greater than the second current amount greater than the first current amount and the present current amount of the control power source CONV is predicted to be reduced to be equal to or less than the first current amount when stopping all of the N number of sub-control operations being performed or scheduled to be performed, the controller 130 stops all of the N number of sub-control operations being performed or scheduled to be performed by setting the value of M to be identical to the value of N, the control operation including the N number of sub-control operations.

According to another embodiment, in a case where the present current amount of the internally generated control power source CONV is equal to or greater than the second current amount greater than the first current amount and the present current amount of the control power source CONV is predicted to be reduced to be equal to or less than the first current amount when stopping some of the N number of sub-control operations being performed or scheduled to be performed, the controller 130 selectively stops only the M number of sub-control operations being a part of the N number of sub-control operations being performed or scheduled to be performed by setting the value of M to be less than the value of N, the control operation including the N number of sub-control operations.

The controller 130 includes information on the amount of current expected to be consumed by each of the plurality of sub-control operations included in the control operation. The amount of current expected to be consumed by each of the plurality of sub-control operations is determined through a test performed in advance during a process of producing the memory system 110 including the controller 130.

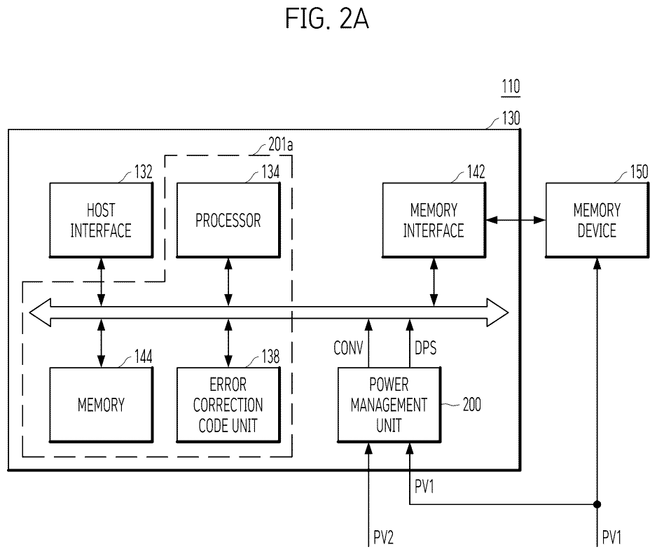

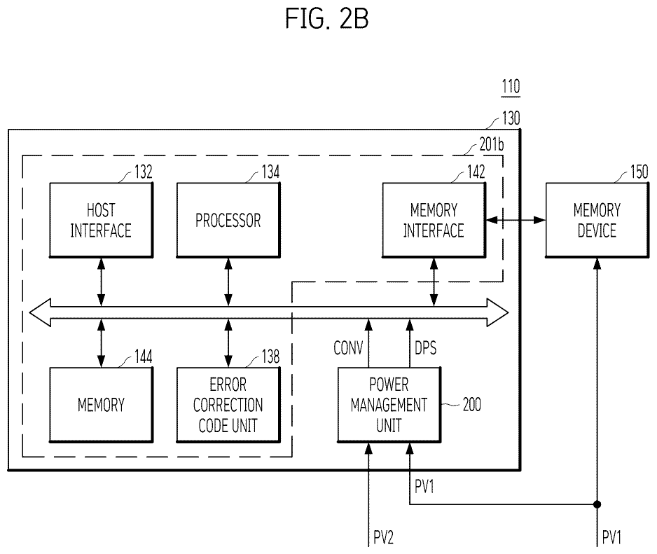

FIGS. 2A and 2B are diagrams for describing the controller included in the memory system in accordance with the first embodiment of the present disclosure.

Referring to FIGS. 2A and 2B, the controller 130 included in the memory system 110 in accordance with the first embodiment of the present disclosure includes a host interface 132, a processor 134, an error correction code (ECC) unit 138, a memory interface 142, a memory 144, and a power management unit 200.

The host 102 and the memory system 110 each may include a controller or an interface for transmitting and receiving signals, data, and the like, in accordance with one or more predetermined protocols. For example, the host interface 132 in the memory system 110 may include an apparatus capable of transmitting signals, data, and the like to the host 102 or receiving signals, data, and the like from the host 102.

The host interface 132 included in the controller 130 may receive signals, commands (or requests), and/or data input from the host 102 via a bus. For example, the host 102 and the memory system 110 may use a predetermined set of rules or procedures for data communication or a preset interface to transmit and receive data therebetween.

Examples of communication standards or interfaces used to transmit/receive data may include various form factors such as 2.5-inch form factor, 1.8-inch form factor, MO-297, MO-300, M.2, and EDSFF (Enterprise and Data Center SSD Form Factor) and various communication standards or interfaces such as USB (Universal Serial Bus), MMC (Multi-Media Card), PATA (Parallel Advanced Technology Attachment), SCSI (Small Computer System Interface), ESDI (Enhanced Small Disk Interface), IDE (Integrated Drive Electronics), PCIe (Peripheral Component Interconnect Express), SAS (Serial-attached SCSI), SATA (Serial Advanced Technology Attachment), and MIPI (Mobile Industry Processor Interface).

According to an embodiment, the host interface 132 is a type of layer for exchanging data with the host 102 and is implemented with, or driven by, firmware called a host interface layer (HIL). According to an embodiment, the host interface 132 can include a command queue.

The Integrated Drive Electronics (IDE) or Advanced Technology Attachment (ATA) may be used as one of the interfaces for transmitting and receiving data and, for example, may use a cable including 40 wires connected in parallel to support data transmission and data reception between the host 102 and the memory system 110. When a plurality of memory systems 110 are connected to a single host 102, the plurality of memory systems 110 may be divided into a master and a slave by using a position or a dip switch to which the plurality of memory systems 110 are connected. The memory system 110 set as the master may be used as a main memory device. The IDE (ATA) may include, for example, Fast-ATA, ATAPI, or Enhanced IDE (EIDE).

A Serial Advanced Technology Attachment (SATA) interface is a type of serial data communication interface that is compatible with various ATA standards of parallel data communication interfaces which are used by Integrated Drive Electronics (IDE) devices. The 40 wires in the IDE interface can be reduced to six wires in the SATA interface. For example, 40 parallel signals for the IDE can be converted into 6 serial signals for the SATA interface. The SATA interface has been widely used because of its faster data transmission and reception rate and its less resource consumption in the host 102 used for the data transmission and reception. The SATA interface may connect up to 30 external devices to a single transceiver included in the host 102. In addition, the SATA interface can support hot plugging that allows an external device to be attached to or detached from the host 102, even while data communication between the host 102 and another device is being executed. Thus, the memory system 110 can be connected or disconnected as an additional device, like a device supported by a universal serial bus (USB) even when the host 102 is powered on. For example, in the host 102 having an eSATA port, the memory system 110 may be freely attached to or detached from the host 102 like an external hard disk.

Small Computer System Interface (SCSI) is a type of serial data communication interface used for connecting a computer or a server with other peripheral devices. The SCSI can provide a high transmission speed, as compared with other interfaces such as IDE and SATA. In the SCSI, the host 102 and at least one peripheral device (e.g., memory system 110) are connected in series, but data transmission and reception between the host 102 and each peripheral device may be performed through a parallel data communication. In the SCSI, it is easy to connect or disconnect a device such as the memory system 110 to or from the host 102. The SCSI can support connections of 15 other devices to a single transceiver included in host 102.

Serial Attached SCSI (SAS) can be understood as a serial data communication version of the SCSI. In the SAS, the host 102 and a plurality of peripheral devices are connected in series, and data transmission and reception between the host 102 and each peripheral device may be performed in a serial data communication scheme. The SAS can support connection between the host 102 and the peripheral device through a serial cable instead of a parallel cable, to easily manage equipment using the SAS and enhance or improve operational reliability and communication performance. The SAS may support connections of eight external devices to a single transceiver included in the host 102.

The Non-volatile memory express (NVMe) is a type of interface based at least on a Peripheral Component Interconnect Express (PCIe) designed to increase performance and design flexibility of the host 102, servers, computing devices, and the like equipped with the non-volatile memory system 110. The PCIe can use a slot or a specific cable for connecting a computing device (e.g., host 102) and a peripheral device (e.g., memory system 110). For example, the PCIe can use a plurality of pins (e.g., 18 pins, 32 pins, 49 pins, or 82 pins) and at least one wire (e.g., ×1, ×4, ×8, or ×16) to achieve high speed data communication over several hundred MB per second (e.g., 250 MB/s, 500 MB/s, 984.6250 MB/s, or 1969 MB/s). According to an embodiment, the PCIe scheme may achieve bandwidths of tens to hundreds of Giga bits per second. The NVMe can support an operation speed of the non-volatile memory system 110, such as an SSD, that is faster than a hard disk.

According to an embodiment, the host 102 and the memory system 110 may be connected through a universal serial bus (USB). The Universal Serial Bus (USB) is a type of scalable, hot-pluggable plug-and-play serial interface that can provide cost-effective standard connectivity between the host 102 and peripheral devices such as a keyboard, a mouse, a joystick, a printer, a scanner, a storage device, a modem, a video camera, and the like. A plurality of peripheral devices such as the memory system 110 may be coupled to a single transceiver included in the host 102.

The error correction unit 138 may check and correct errors in data transmitted between the controller 130 and the memory device 150. The error correction unit 138 may be implemented as a separate module, circuit or firmware in the controller 130, but also may be implemented in the memory device 150 according to an embodiment.

The error correction circuitry 138 may include all circuits, modules, systems, and/or devices for performing the error correction operation based on at least one of the above-described codes.

The error correction circuitry 138 can correct error bits of data read from the memory device 150 and may include an error correction code (ECC) encoder and an ECC decoder. The ECC encoder may perform error correction encoding of data to be programmed in the memory device 150 to generate encoded data into which a parity bit is added and store the encoded data in the memory device 150. The ECC decoder can detect and correct error bits contained in the data read from the memory device 150 when the controller 130 reads the data stored in the memory device 150. For example, after performing error correction decoding on the data read from the memory device 150, the error correction circuitry 138 determines whether the error correction decoding has succeeded or not, and outputs an instruction signal, e.g., a correction success signal or a correction fail signal, based on a result of the error correction decoding. The error correction circuitry 138 may use a parity bit, which has been generated during the ECC encoding process for the data stored in the memory device 150, to correct the error bits of the read data entries. When the number of the error bits is greater than or equal to the number of correctable error bits, the error correction circuitry 138 may not correct the error bits and instead may output the correction fail signal indicating failure in correcting the error bits.

According to an embodiment, the error correction circuitry 138 may perform an error correction operation based on a coded modulation such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), a Block coded modulation (BCM), or the like.

An operation performed by the ECC decoder, that is, an operation of detecting and correcting errors included in read data, may be an operation distinct from the above-described read retry operation. According to an embodiment, the controller 130 may perform an error correction decoding operation through the ECC decoder when errors equal to or greater than a reference value occur even though the read retry operation, which is a repeated read operation, has been performed using the plurality of read retry levels.

The memory interface 142 may serve as an interface for handling commands and data transferred between the controller 130 and the memory device 150, to allow the controller 130 to control the memory device 150 in response to a command or a request input from the host 102. The memory interface 142 may generate a control signal for the memory device 150 and may process data input to, or output from, the memory device 150 under the control of the processor 134 in a case when the memory device 150 is a flash memory.

For example, when the memory device 150 includes a NAND flash memory, the memory interface 142 includes a NAND flash controller (NFC). The memory interface 142 can provide an interface for handling commands and data between the controller 130 and the memory device 150. In accordance with an embodiment, the memory interface 142 can be implemented through, or driven by, firmware called a Flash Interface Layer (FIL) for exchanging data with the memory device 150.

According to an embodiment, the memory interface 142 may support an open NAND flash interface (ONFi), a toggle mode, or the like, for data input/output with the memory device 150. For example, the ONFi may use a data path (e.g., a channel, a way, etc.) that includes at least one signal line capable of supporting bi-directional transmission and reception in a unit of 8-bit or 16-bit data. Data communication between the controller 130 and the memory device 150 can be achieved through at least one interface regarding an asynchronous single data rate (SDR), a synchronous double data rate (DDR), a toggle double data rate (DDR), or the like.

The memory 144 may be used as a working memory of the memory system 110 or the controller 130, while temporarily storing transactional data for operations performed in the memory system 110 and the controller 130. For example, the memory 144 may temporarily store read data entries output from the memory device 150 in response to a read request from the host 102 before the read data entries are output to the host 102. In addition, the controller 130 may temporarily store write data entries input from the host 102 in the memory 144 before programming the write data entries in the memory device 150. When the controller 130 controls operations, such as a data read operation, a data write or program operation, a data erase operation, etc., of the memory device 150, data transmitted between the controller 130 and the memory device 150 of the memory system 110 may be temporarily stored in the memory 144.

In an embodiment, the memory 144 may be implemented with a volatile memory. For example, the memory 144 may be implemented with a static random access memory (SRAM), a dynamic random access memory (DRAM), or both. Although FIG. 1 illustrates, for example, the memory 144 disposed within the controller 130, embodiments are not limited thereto. The memory 144 may be located within or external to the controller 130. For instance, the memory 144 may be embodied by an external volatile memory having a memory interface transferring data and/or signals between the memory 144 and the controller 130. According to an embodiment, the above-described information storage region 161 and retry storage region 162 may be included in the memory 144.

In addition to the read data entries or write data entries, the memory 144 may store information, e.g., map data, read requests, program requests, etc. used for inputting or outputting data between the host 102 and the memory device 150. According to an embodiment, the memory 144 may include one or more of a command queue, a program memory, a data memory, a write buffer/cache, a read buffer/cache, a data buffer/cache, a map buffer/cache, and so on. The controller 130 may allocate some storage space in the memory 144 for a component which is established to carry out a data input/output operation. For example, the write buffer established in the memory 144 may be used to temporarily store target data subject to a program operation.

The processor 134 may control the overall operations of the memory system 110. For example, the processor 134 can control a program operation or a read operation of the memory device 150 in response to a write request or a read request entered from the host 102.

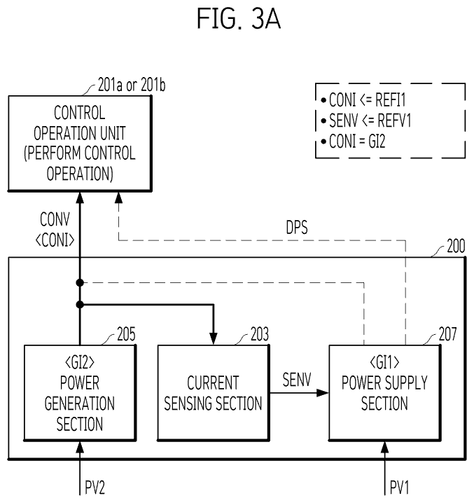

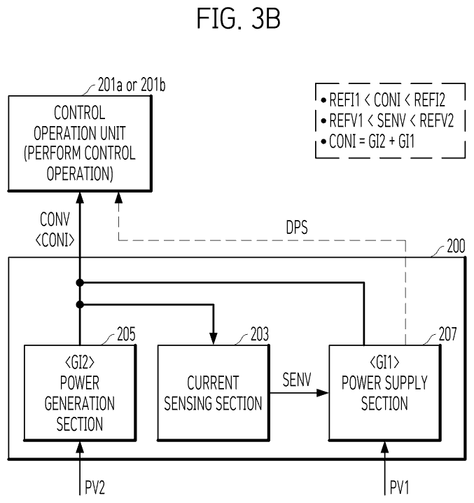

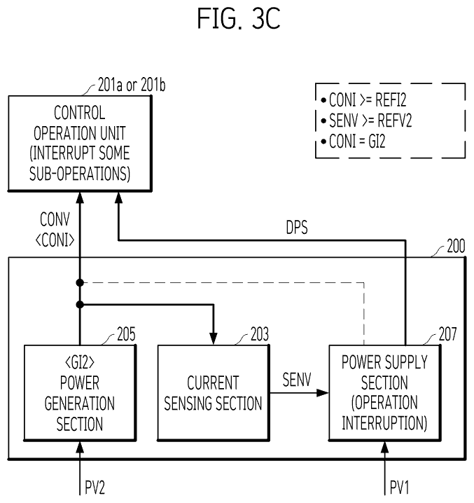

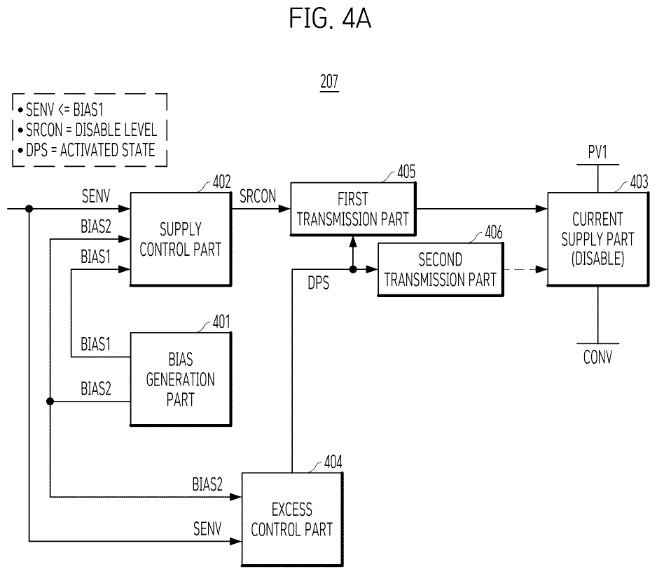

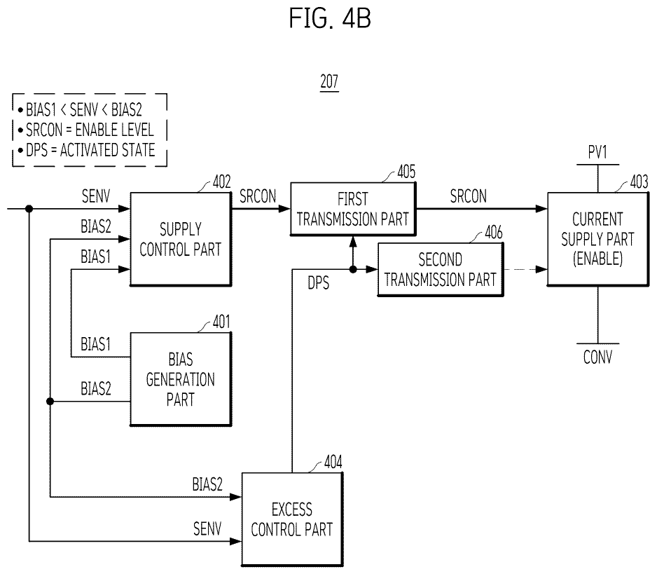

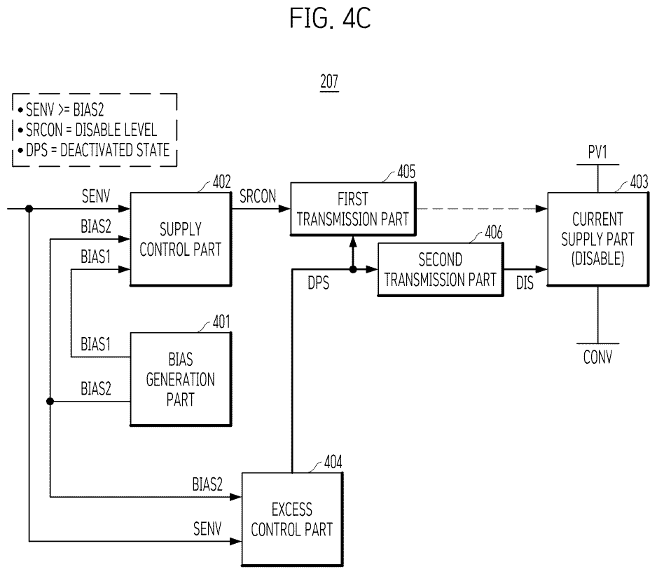

According to an embodiment, the processor 134 may execute firmware to control the program operation or the read operation in the memory system 110. Herein, the firmware may be referred to as a flash translation layer (FTL). An example of the FTL will be described in detail, referring to FIGS. 3 and 4. According to an embodiment, the processor 134 may be implemented with a microprocessor, a central processing unit (CPU), or the like.

According to an embodiment, the memory system 110 may be implemented with at least one multi-core processor. The multi-core processor is a type of circuit or chip in which two or more cores, which are considered distinct processing regions, are integrated. For example, when a plurality of cores in the multi-core processor drive or execute a plurality of flash translation layers (FTLs) independently, a data input/output speed (or performance) of the memory system 110 may be improved. According to an embodiment, the data input/output (I/O) operations in the memory system 110 may be independently performed through different cores in the multi-core processor.

The processor 134 controls the entire operations of the memory system 110. In particular, the processor 134 controls a program operation or a read operation for the memory device 150, in response to a write request or a read request from the host 102. The processor 134 drives firmware which is referred to as a flash translation layer (FTL), to control general operations of the memory system 110. The processor 134 may be realized by a microprocessor or a central processing unit (CPU).

For instance, the controller 130 performs an operation requested from the host 102, in the memory device 150. That is, the controller 130 performs a command operation corresponding to a command received from the host 102, with the memory device 150, through the processor 134 embodied by a microprocessor or a central processing unit (CPU). The controller 130 may perform a foreground operation as a command operation corresponding to a command received from the host 102. For example, the controller 130 may perform a program operation corresponding to a write command, a read operation corresponding to a read command, an erase operation corresponding to an erase command.

The controller 130 may also perform a background operation for the memory device 150, through the processor 134 embodied by a microprocessor or a central processing unit (CPU). The background operation for the memory device 150 may include an operation of copying data stored in a memory block among the memory blocks 152, 154 and 156 of the memory device 150 to another memory block, for example, a garbage collection (GC) operation. The background operation may include an operation of swapping data between one or more of the memory blocks 152, 154 and 156 of the memory device 150, for example, a wear leveling (WL) operation, a read reclaim (RR) operation and media scan operation. The background operation may include an operation of storing map data retrieved from the controller 130 in the memory blocks 152, 154 and 156 of the memory device 150, for example, a map flush operation. The background operation may include a bad management operation for the memory device 150, which may include checking for and processing a bad block among the plurality of memory blocks 152, 154 and 156 in the memory device 150.

The power management unit 200 included in the controller 130 generates the control power source CONV used by the controller 130 in order to perform the control operation.

According to an embodiment, referring to FIG. 2A, among the components included in the controller 130, the processor 134, the error correction code (ECC) unit 138, and the memory 144 operate using the control power source CONV generated by the power management unit 200. In addition, among the components included in the controller 130, the host interface 132 and the memory interface 142 operate by receiving a separate external power source (not illustrated in the drawing) different from the control power source CONV.

According to another embodiment, referring to FIG. 2B, among the components included in the controller 130, all components except the power management unit 200, that is, the processor 134, the error correction code (ECC) unit 138, the host interface 132, the memory interface 142, and the memory 144 operate using the control power source CONV generated by the power management unit 200.

In the present disclosure, among the components included in the controller 130, components that perform the control operation for controlling the set internal operation performed in the memory device 150 using the control power source CONV generated by the power management unit 200 are grouped and referred to as a control operation section 201a or 201b. Accordingly, in FIG. 2A, the components of the controller 130 that operate by receiving the control power source CONV, that is, the processor 134, the error correction code (ECC) unit 138, and the memory 144 are referred to as the control operation section 201a. Likewise, in FIG. 2B, the components of the controller 130 that operate by receiving the control power source CONV, that is, the processor 134, the error correction code (ECC) unit 138, the host interface 132, the memory interface 142, and the memory 144, are referred to as the control operation section 201a.

The distinction of the components of the controller 130 in FIGS. 2A and 2B as the control operation section 201a or 201b is merely an example for the convenience of description in the present disclosure, and other types of distinctions are actually possible depending on the type of the memory system 110 and the designer's selection. In addition, whether to use the controller 130 illustrated in FIG. 2A or the controller 130 illustrated in FIG. 2B varies depending on the type of the memory system 110 and the designer's selection. In addition, since the configuration of separating the power (not illustrated) supplied to the components 132 and 142 included in the controller 130 and the power CONV supplied to the other components 134, 138, and 144 as in FIG. 2A and the configuration of supplying one power CONV to all components 132, 142, 134, 138, and 144 included in the controller 130 as in FIG. 2B are already known configurations, a more detailed description thereof is omitted.

More specifically, the power management unit 200 generates the control power source CONV by receiving current from the second power source PV2 generated by the power generation device 170a or 170b (see FIGS. 1A and 1B) when the present current amount of the control power source CONV is equal to or less than the first current amount. When the present current amount of the control power source CONV is equal to or less than the first current amount, it means that the current amount of the control power source CONV required for the control operation section 201a or 201b to perform the control operation is less than the maximum current amount suppliable through the second power source PV2. Accordingly, the control operation section 201a or 201b normally performs the control operation with only the control power source CONV generated by the power management unit 200 receiving the current of the second power source PV2.

When the present current amount of the control power source CONV exceeds the first current amount, the power management unit 200 generates the control power source CONV by simultaneously receiving the first power source PV1 and the second power source PV2 generated by the power generation device 170a or 170b. That is, when the present current amount of the control power source CONV exceeds the first current amount, the power management unit 200 generates the control power source CONV by using the current supplied from the second power source PV2, and also increases the present current amount of the control power source CONV by simultaneously supplying current from a node of the first power source PV1 to a node of the control power source CONV. In such a case, when the present current amount of the control power source CONV exceeds the first current amount, it means that the current amount of the control power source CONV required for the control operation section 201a or 201b to perform the control operation is greater than the maximum current amount suppliable through the second power source PV2. Accordingly, the control operation section 201a or 201b performs the control operation by using the control power source CONV generated by the power management unit 200 receiving both the current of the second power source PV2 and the current of the first power source PV1.

The control operation performed by the control operation section 201a or 201b includes a plurality of sub-control operations.

For example, when the control operation performed by the control operation section 201a or 201b is an operation for controlling a program operation of the memory device 150, the plurality of sub-control operations may include an operation for transmitting a program command, program data, and an address by referring to mapping information, an operation for setting a program voltage level, an operation for transmitting program data, an operation for checking whether the program operation is successful, and the like.

For another example, when the control operation performed by the control operation section 201a or 201b is an operation for controlling a read operation of the memory device 150, the plurality of sub-control operations may include an operation for searching and transmitting a read address through mapping information, an operation for setting a read voltage level, an operation for correcting an error occurring in read data, an operation for outputting read data to the host, and the like.

The control operation performed by the control operation section 201a or 201b includes various other types of operations in addition to the program operation and read operation illustrated, and this is adjusted in various ways depending on the type of memory device and the designer's selection.

When the present current amount of the control power source CONV is equal to or greater than the second current amount greater than the first current amount, the power management unit 200 requests (DPS) the control operation section 201a or 201b to perform an operation for reducing the present current amount of the control power source CONV. When the present current amount of the control power source CONV is equal to or greater than the second current amount greater than the first current amount, the power management unit 200 stops the operation for receiving current from the first power source PV1 generated by the power generation device 170a or 170b, which has been started to be performed when the present current amount of the control power source CONV is less than the second current amount, and performs the operation for generating the control power source CONV by receiving current from the second power source PV2.

In such a case, the control operation section 201a or 201b reduces the present current amount of the control power source CONV by stopping the M number of sub-control operations among the N number of sub-control operations being performed or scheduled to be performed, in response to the request (DPS) of the power management unit 200, the control operation including the N number of sub-control operations. Here, N is a natural number equal to or greater than 1, and M is a natural number equal to or greater than 1 and equal to or less than N. In addition, the control operation section 201a or 201b predicts the current amount of the control power source CONV that is reduced in amount by stopping the M number of sub-control operations among the N number of sub-control operations being performed or scheduled to be performed, in response to the request (DPS) of the power management unit 200, and adjusts the value of M so that the present current amount of the control power source CONV becomes equal to or less than the first current amount according to the prediction result, the control operation including the N number of sub-control operations.

In summary, when the current amount of the control power source CONV is equal to or greater than the second current amount, it means that the current amount of the control power source CONV required for the control operation section 201a or 201b to perform the control operation is greater than the sum of the maximum current amount suppliable through the second power source PV2 and the maximum current amount suppliable through the first power source PV1. Accordingly, the control operation section 201a or 201b is not able to normally perform the control operation with only the control power source CONV generated by the power management unit 200 receiving both the current of the second power source PV2 and the current of the first power source PV1.

Therefore, when the present current amount of the control power source CONV is detected to be equal to or greater than the second current amount, the power management unit 200 requests (DPS) the control operation section 201a or 201b to perform an operation for reducing the present current amount of the control power source CONV. In addition, in response to the request (DPS) of the power management unit 200, the control operation section 201a or 201b reduces the present current amount of the control power source CONV by stopping the M number of sub-control operations among the N number of sub-control operations being performed or scheduled to be performed, the control operation including the N number of sub-control operations.

According to an embodiment, in a case where the present current amount of the control power source CONV is expected to decrease below the first current amount only when all N number of sub-control operations being performed or scheduled to be performed are stopped in response to the request (DPS) of the power management unit 200, the control operation section 201a or 201b stops all N number of sub-control operations being performed or scheduled to be performed by setting the value of M to be identical to the value of N, the control operation including the N number of sub-control operations.

According to another embodiment, when the present current amount of the control power source CONV is expected to decrease below the first current amount even though some of the N number of sub-control operations being performed or scheduled to be performed are stopped in response to the request (DPS) of the power management unit 200, the control operation section 201a or 201b selectively stops only the M number of sub-control operations being a part of the M number of sub-control operations among the N number of sub-control operations being performed or scheduled to be performed by setting the value of M to be less than the value of N, the control operation including the N number of sub-control operations.

The control operation section 201a or 201b includes information on the amount of current expected to be consumed by each of the plurality of sub-control operations included in the control operation. In such a case, the amount of current expected to be consumed by each of the plurality of sub-control operations is determined through a test performed in advance during the process of producing the memory system 110 including the control operation section 201a or 201b.

In the above description, the maximum current amount suppliable to the control power source CONV through the second power source PV2 is a value greater than the first current amount used as an operation reference of the power management unit 200. Likewise, in the above description, the amount of current obtained by summing the maximum current amount suppliable to the control power source CONV through the second power source PV2 and the maximum current amount suppliable to the control power source CONV through the first power source PV1 is a value greater than the second current amount used as the operation reference of the power management unit 200.

FIGS. 3A to 3C are diagrams for describing an operation in which the controller in accordance with the first embodiment of the present disclosure generates a control power source.

Referring to FIGS. 3A to 3C, the power management unit 200 included in the controller 130 in accordance with the first embodiment of the present disclosure includes a current sensing section 203, a power generation section 205, and a power supply section 207.

First, as described with reference to FIGS. 2A and 2B, when the present current amount of the control power source CONV is equal to or less than the first current amount, the power management unit 200 generates the control power source CONV by receiving the second power source PV2 generated by the power generation device 170a or 170b (see FIGS. 1A and 1B).

In addition, when the present current amount of the control power source CONV exceeds the first current amount, the power management unit 200 generates the control power source CONV by simultaneously receiving the first power source PV1 and the second power source PV2 generated by the power generation device 170a or 170b.

In addition, when the present current amount of the control power source CONV is equal to or greater than the second current amount greater than the first current amount, the power management unit 200 requests (DPS) the control operation section 201a or 201b to perform an operation for reducing the present current amount of the control power source CONV.

Specifically, the current sensing section 203 included in the power management unit 200 senses the present current amount of the control power source CONV. That is, the current sensing section 203 generates a sensing signal SENV whose level is adjusted according to the present current amount of the control power source CONV.

When a present current amount CONI of the control power source CONV is equal to or less than a first current amount REFI1 (CONI<=REFI1), the current sensing section 203 generates a sensing signal SENV having a level equal to or lower than a first reference level REFV1.

When the present current amount CONI of the control power source CONV is equal to or greater than a second current amount REFI2 (CONI>=REFI2), the current sensing section 203 generates a sensing signal SENV having a level equal to or higher than a second reference level REFV2.

When the present current amount CONI of the control power source CONV is between the first and second current amounts REFI1 and REFI2 (REFI1<CONI<REFI2), the current sensing section 203 generates the sensing signal SENV having a level set between the first and second reference levels REFV1 and REFV2.

The power generation section 205 included in the power management unit 200 generates the control power source CONV by receiving the second power source PV2. That is, when the second power source PV2 is supplied from the outside for the operation of the controller 130, the power generation section 205 generates the control power source CONV in response to the supply of the second power source PV2. In such a case, the power generation section 205 supplies current GI2 from a node of the second power source PV2 to the node of the control power source CONV through the operation of generating the control power source CONV by receiving the second power source PV2. For example, the power generation section 205 may supply the current GI2 of up to 2000 mA from the node of the second power source PV2 to the node of the control power source CONV through the operation of generating the control power source CONV by receiving the second power source PV2.

According to an embodiment, the power generation section 205 operates in an LDO (Low Dropout Regulator) mode, that is, a low-voltage differential linear voltage regulator mode. For example, the power generation section 205 may receive the second power source PV2 at a 1.2 V level and operate in the LDO mode to generate the control power source CONV at a 0.75 V level.

The power supply section 207 included in the power management unit 200 adjusts the amount of a current GI1 supplied from the node of the first power source PV1 to the node of the control power source CONV in response to the output signal SENV of the current sensing section 203. That is, the power supply section 207 adjusts the amount of the current GI1 supplied from the node of the first power source PV1 to the node of the control power source CONV according to the level of the sensing signal SENV output from the current sensing section 203. In such a case, the power supply section 207 only performs an operation of adjusting the amount of the current GI1 supplied from the node of the first power source PV1 to the node of the control power source CONV, and may not perform an operation of directly generating the control power source CONV like the power generation section 205, that is, regulating to maintain the voltage level (for example, 0.75 V level) of the control power source CONV.

The power supply section 207 supplies the current GI1 from the node of the first power source PV1 to the node of the control power source CONV in a duration where the level of the sensing signal SENV output from the current sensing section 203 is between the first and second reference levels REFV1 and REFV2.

In addition, the power supply section 207 supplies no current from the node of the first power source PV1 to the node of the control power source CONV in a duration where the level of the sensing signal SENV output from the current sensing section 203 is equal to or lower than the first reference level REFV1. That is, the power supply section 207 stops the operation of supplying current in a duration where the sensing signal SENV output from the current sensing section 203 is equal to or lower than the first reference level REFV1.

In addition, the power supply section 207 supplies no current from the node of the first power source PV1 to the node of the control power source CONV in a duration where the level of the sensing signal SENV output from the current sensing section 203 is equal to or higher than the second reference level REFV2. That is, the power supply section 207 stops the operation of supplying current in a duration where the sensing signal SENV output from the current sensing section 203 is equal to or higher than the second reference level REFV2. In addition, in response to the fact that the level of the sensing signal SENV output from the current sensing section 203 is equal to or higher than the second reference level REFV2, the power supply section 207 requests (DPS) the control operation section 201a or 201b to perform the operation for reducing the present current amount of the control power source CONV.

According to an embodiment, the power supply section 207 includes a dependent current source (DCS) circuit. That is, the power supply section 207 includes a dependent current source circuit for adjusting the amount of the current GI1 flowing between the node of the first power source PV1 and the node of the control power source CONV according to the level of the sensing signal SENV.

According to another embodiment, the power supply section 207 includes a switched-capacitor (SC) converter circuit. That is, the power supply section 207 includes a switched-capacitor converter circuit for adjusting the amount of the current GI1 flowing from the node of the first power source PV1 to the node of the control power source CONV by adjusting an operation of a switch element included therein according to the level of the sensing signal SENV and thus controlling the charging and discharging of a capacitor element connected between the node of the first power source PV1 and the node of the control power source CONV.

Referring to FIG. 3A, when the present current amount of the control power source CONV is equal to or less than the first current amount REFI1 (CONI<=REFI1), the operation of the power management unit 200 can be seen.

First, in FIG. 3A, the second power source PV2 is supplied, and the power generation section 205 generates the control power source CONV by receiving the second power source PV2. That is, the power generation section 205 supplies the current GI2 from the node of the second power source PV2 to the node of the control power source CONV.

The current sensing section 203 detects that the present current amount CONI of the control power source CONV is equal to or less than the first current amount REFI1 (CONI<=REFI1), and sets the level of the sensing signal SENV to a level equal to or lower than the first reference level REFV1 (SENV<=REFV1).

When the present current amount CONI of the control power source CONV is equal to or less than the first current amount REFI1 (SENV<=REFV1), it means that the current amount of the control power source CONV required for the control operation section 201a or 201b to perform the control operation is less than the maximum current amount suppliable through the second power source PV2. That is, it means that the control operation section 201a or 201b can perform the control operation even in a state where no current is supplied from the node of the first power source PV1 to the node of the control power source CONV through the power supply section 207.

Accordingly, the power supply section 207 may not perform an operation of supplying current in response to the sensing signal SENV having a level equal to or lower than the first reference level REFV1 (SENV<32 REFV1) (operation interruption). That is, the power supply section 207 prevents current from flowing between the node of the first power source PV1 and the node of the control power source CONV in response to the sensing signal SENV having a level equal to or lower than the first reference level REFV1 (SENV<=REFV1).

In summary, in a state like FIG. 3A, that is, the power generation section 205 performs an operation of generating the control power source CONV and supplies the current GI2 from the node of the second power source PV2 to the node of the control power source CONV, but since the power supply section 207 is in a state of ‘operation interruption’ and supplies no current to the node of the control power source CONV, the present current amount CONI of the control power source CONV is identical to the current GI2 supplied to the node of the control power source CONV through the power generation section 205 (CONI=GI2).

Referring to FIG. 3B, when the present current amount of the control power source CONV is between the first and second current amounts REFI1 and REFI2 (REFI1<CONI<REFI2), the operation of the power management unit 200 can be seen.

First, in FIG. 3B, the second power source PV2 is supplied, and the power generation section 205 generates the control power source CONV by receiving the second power source PV2. That is, the power generation section 205 supplies the current GI2 from the node of the second power source PV2 to the node of the control power source CONV.

The current sensing section 203 detects that the present current amount CONI of the control power source CONV is between the first and second current amounts REFI1 and REFI2 (REFI1<CONI<REFI2), and sets the level of the sensing signal SENV to a level between the first and second reference levels REFV1 and REFV2 (REFV1<SENV<REFV2).

When the present current amount CONI of the control power source CONV is between the first and second current amounts REFI1 and REFI2 (REFI1<CONI<REFI2), it means that the current amount of the control power source CONV required for the control operation section 201a or 201b to perform the control operation is greater than the maximum current amount suppliable through the second power source PV2. That is, only when the power management unit 200 generates the control power source CONV by receiving both the current of the second power source PV2 and the current of the first power source PV1, it can be seen that the control operation section 201a or 201b normally performs the control operation by using the control power source CONV.

Accordingly, the power supply section 207 performs an operation of supplying current in response to the sensing signal SENV having a level between the first and second reference levels REFV1 and REFV2 (REFV1<SENV<REFV2). That is, the power supply section 207 supplies the current GI1 from the node of the first power source PV1 to the node of the control power source CONV in response to the sensing signal SENV having a level between the first and second reference levels REFV1 and REFV2 (REFV1<SENV<REFV2).

In summary, in a state like FIG. 3B, that is, in a state where the power generation section 205 supplies the current GI2 from the node of the second power source PV2 to the node of the control power source CONV by performing an operation of generating the control power source CONV and the power supply section 207 also performs an operation of supplying the current GI1 from the node of the first power source PV1 to the node of the control power source CONV, the present current amount CONI of the control power source CONV is the sum (CONI=GI2+GI1) of the current GI2 supplied to the node of the control power source CONV through the power generation section 205 and the current GI1 supplied to the node of the control power source CONV through the power supply section 207.

Referring to FIG. 3C, when the present current amount of the control power source CONV is equal to or greater than the second current amount REFI2 (CONI>=REFI2), the operation of the power management unit 200 can be seen.

First, in FIG. 3C, the second power source PV2 is supplied, and the power generation section 205 generates the control power source CONV by receiving the second power source PV2. That is, the power generation section 205 supplies the current GI2 from the node of the second power source PV2 to the node of the control power source CONV.

The current sensing section 203 detects that the present current amount CONI of the control power source CONV is equal to or greater than the second current amount REFI2 (CONI>=REFI2), and sets the level of the sensing signal SENV to a level equal to or higher than the second reference level REFV2 (SENV>=REFV2).

When the present current amount CONI of the control power source CONV is equal to or greater than the second current amount REFI2 (SENV>=REFV2), it means that the current amount of the control power source CONV required for the control operation section 201a or 201b to perform the control operation is greater than the sum of the maximum current amount suppliable through the second power source PV2 and the maximum current amount suppliable through the first power source PV1. That is, it means that even though the current GI2 is supplied from the node of the second power source PV2 to the node of the control power source CONV through the power generation section 205 at a maximum amount (for example, 2000 mA) and at the same time, the current GI1 is supplied from the node of the first power source PV1 to the node of the control power source CONV through the power supply section 207 at a maximum amount (for example, 300 mA), it is less than the current amount of the control power source CONV required by the control operation section 201a or 201b.

Therefore, when the present current amount CONI of the control power source CONV is equal to or greater than the second current amount REFI2 (SENV>=REFV2), the power supply section 207 requests (DPS) the control operation section 201a or 201b to perform an operation for reducing the present current amount of the control power source CONV. In addition, when the present current amount CONI of the control power source CONV is equal to or greater than the second current amount REFI2 (SENV>=REFV2), the power supply section 207 stops the operation of receiving the current GI1 from the first power source PV1, which has been started to be performed when the present current amount of the control power source CONV is less than the second current amount (operation stop). Of course, since the power generation section 205 continues to operate regardless of the interruption of the operation of the power supply section 207, the current GI2 is continuously supplied from the node of the second power source PV2 to the node of the control power source CONV.

In such a case, the control operation section 201a or 201b reduces the present current amount of the control power source CONV by interrupting the M number of sub-control operations among the N number of sub-control operations being performed or scheduled to be performed, in response to the request (DPS) of the power supply section 207 (interrupting some sub-operations), the control operation including the N number of sub-control operations. Here, N is a natural number equal to or greater than 1, and M is a natural number equal to or greater than 1 and equal to or less than N. In addition, the control operation section 201a or 201b predicts the current amount of the control power source CONV that is reduced in amount by stopping the M number of sub-control operations among the N number of sub-control operations being performed or scheduled to be performed in response to the request (DPS) of the power supply section 207, and adjusts the value of M so that the present current amount of the control power source CONV becomes equal to or less than the first current amount according to the predicted result, the control operation including the N number of sub-control operations.

In summary, in a state like FIG. 3C, that is, the power generation section 205 performs an operation of generating the control power source CONV and supplies the current GI2 from the node of the second power source PV2 to the node of the control power source CONV, but since the power supply section 207 is in a state of ‘operation interruption’ and supplies no current to the node of the control power source CONV, the present current amount CONI of the control power source CONV is identical to the current GI2 supplied to the node of the control power source CONV through the power generation section 205 (CONI=GI2).

FIGS. 4A to 4C are diagrams for describing an operation in which the power supply section included in the controller in accordance with the first embodiment of the present disclosure supplies a current.

Referring to FIGS. 4A to 4C, the power supply section 207 included in the controller 130 in accordance with the first embodiment of the present disclosure includes a bias generation part 401, a supply control part 402, a current supply part 403, an excess control part 404, a first transmission part 405, and a second transmission part 406.

First, the power supply section 207 adjusts the amount of the current GI1 supplied from the node of the first power source PV1 to the node of the control power source CONV according to the level of the sensing signal SENV output from the current sensing section 203.

In addition, the power supply section 207 supplies the current GI1 from the node of the first power source PV1 to the node of the control power source CONV in a duration where the level of the sensing signal SENV output from the current sensing section 203 is between the first and second reference levels REFV1 and REFV2.

In addition, the power supply section 207 supplies no current from the node of the first power source PV1 to the node of the control power source CONV in a duration where the level of the sensing signal SENV output from the current sensing section 203 is equal to or lower than the first reference level REFV1.

In addition, the power supply section 207 supplies no current from the node of the first power source PV1 to the node of the control power source CONV in a duration where the level of the sensing signal SENV output from the current sensing section 203 is equal to or higher than the second reference level REFV2.

That is, the power supply section 207 stops the operation of supplying current in a duration where the level of the sensing signal SENV output from the current sensing section 203 is equal to or lower than the first reference level REFV1 or in a duration where the level of the sensing signal SENV output from the current sensing section 203 is equal to or higher than the second reference level REFV2.

In addition, the power supply section 207 requests (DPS) the control operation section 201a or 201b to perform an operation for reducing the present current amount of the control power source CONV in response to the present current amount CONI of the control power source CONV being equal to or greater than the second current amount REFI2 (SENV>=REFV2).

The bias generation part 401 included in the power supply section 207 generates a first bias BIAS1 having the first reference level REFV1 and a second bias BIAS2 having the second reference level REFV2.

The supply control part 402 included in the power supply section 207 compares the level of the sensing signal SENV with the level of the first bias BIAS1 and the level of the second bias BIAS2, respectively, and adjusts a level of a signal SRCON output in response to the comparison result.

According to an embodiment, when the level of the sensing signal SENV is equal to or lower than the level of the first bias BIAS1 having the first reference level REFV1, the supply control part 402 outputs the signal SRCON having a level (hereinafter, referred to as a “disable level”) that may disable the flow of current from the node of the first power source PV1 to the node of the control power source CONV.

According to another embodiment, when the level of the sensing signal SENV is between the level of the first bias BIAS1 having the first reference level REFV1 and the level of the second bias BIAS2 having the second reference level REFV2, the supply control part 402 outputs the signal SRCON having a level (hereinafter, referred to as an ‘enable level’) that may enable current to flow from the node of the first power source PV1 to the node of the control power source CONV. The enable level is determined between a first specific level and a second specific level that are set in advance. For example, in response to the output signal SRCON having the first specific level, the amount of the current flowing between the node of the first power source PV1 and the node of the control power source CONV may be relatively greater than the amount of the current flowing between the node of the first power source PV1 and the node of the control power source CONV in response to the output signal SRCON having the second specific level.

According to further another embodiment, when the level of the sensing signal SENV is equal to or higher than the level of the second bias BIAS2 having the second reference level REFV2, the supply control part 402 outputs the signal SRCON having the disable level.

The current supply part 403 included in the power supply section 207 supplies the current GI1 having an amount corresponding to the level of the signal SRCON output from the supply control part 402 from the node of the first power source PV1 to the node of the control power source CONV.

According to an embodiment, the current supply part 403 operates so that no current flows between the node of the first power source PV1 and the node of the control power source CONV in response to the fact that the signal SRCON output from the supply control part 402 is at a disable level. In this way, the operation of the current supply part 403 that prevents current from flowing between the node of the first power source PV1 and the node of the control power source CONV is referred to as a ‘disable operation’.

According to another embodiment, the current supply part 403 operates to allow the current GI1 to flow from the node of the first power source PV1 to the node of the control power source CONV in response to the fact that the signal SRCON output from the supply control part 402 is at an enable level. In this way, the operation of the current supply part 403 that allows current to flow between the node of the first power source PV1 and the node of the control power source CONV is referred to as an ‘enable operation’. For example, the current supply part 403 may operate to allow a relatively large amount of current GI1 to flow from the node of the first power source PV1 to the node of the control power source CONV as the level of the signal SRCON output from the supply control part 402 is relatively closer to the first specific level between the first specific level and the second specific level.

The excess control part 404 included in the power supply section 207 compares the level of the sensing signal SENV with the level of the second bias BIAS2 and outputs a transmission control signal DPS staying deactivated while the level of the sensing signal SENV is equal to or higher than the second reference level REFV2. In addition, the excess control part 404 compares the level of the sensing signal SENV with the level of the second bias BIAS2 and outputs a transmission control signal DPS staying activated while the level of the sensing signal SENV is lower than the second reference level REFV2.

The first transmission part 405 included in the power supply section 207 transmits the signal SRCON output from the supply control part 402 to the current supply part 403 in a duration where the transmission control signal DPS output from the excess control part 404 is activated. In addition, the first transmission part 405 may not transmit the signal SRCON output from the supply control part 402 to the current supply part 403 in a duration where the transmission control signal DPS output from the excess control part 404 is deactivated.

The second transmission part 406 included in the power supply section 207 outputs a disable signal DIS for switching the current supply part 403 to a disabled operation state in the duration where the transmission control signal DPS output from the excess control part 404 is deactivated. In addition, the second transmission part 406 may not output the disable signal DIS for switching the current supply part 403 to the disabled operation state in the duration where the transmission control signal DPS output from the excess control part 404 is activated.

On the other hand, the operation of transitioning the transmission control signal DPS output from the excess control part 404 from an activated state to a deactivated state is an operation of the power supply section 207 requesting the control operation section 201a or 201b to perform an operation for reducing the present current amount of the control power source CONV. That is, the control operation section 201a or 201b reduces the present current amount of the control power source CONV by stopping the M number of sub-control operations among the N number of sub-control operations being performed or scheduled to be performed in response to the fact that the transmission control signal DPS output from the excess control part 404 included in the power supply section 207 transitions from an activated state to a deactivated state, the control operation including the N number of sub-control operations.

Referring to FIG. 4A, when the level of the sensing signal SENV is equal to or lower than the level of the first bias BIAS1 having the first reference level REFV1 (SENV<=BIAS1), the operation of the power supply section 207 can be seen.

First, the bias generation part 401 generates the first bias BIAS1 having the first reference level REFV1 and the second bias BIAS2 having the second reference level REFV2.

Subsequently, the supply control part 402 checks that the level of the sensing signal SENV is equal to or lower than the level of the first bias BIAS1 and outputs a signal SRCON having a disable level according to the check result.

Subsequently, the excess control part 404 checks that the level of the sensing signal SENV is lower than the level of the second bias BIAS2 and outputs a transmission control signal DPS of an activated state according to the check result.

Subsequently, the first transmission part 405 transmits the signal SRCON output from the supply control part 402 to the current supply part 403 in response to the transmission control signal DPS, which is in the activated state and output from the excess control part 404.

Subsequently, the second transmission part 406 may not output the disable signal DIS in response to the transmission control signal DPS, which is in the activated state and output from the excess control part 404 (dotted line).

In summary, in response to the fact that the level of the sensing signal SENV is equal to or lower than the level of the first bias BIAS1 having the first reference level REFV1 (SENV<=BIAS1), the signal SRCON having the disable level in the supply control part 402 is transmitted to the current supply part 403 through the first transmission part 405.

Accordingly, the current supply part 403 operates so that no current flows between the node of the first power source PV1 and the node of the control power source CONV in response to the output signal SRCON of the supply control part 402 having the disable level.

Referring to FIG. 4B, when the level of the sensing signal SENV is between the level of the first bias BIAS1 having the first reference level REFV1 and the level of the second bias BIAS2 having the second reference level REFV2 (BIAS1<SENV<BIAS2), the operation of the power supply section 207 can be seen.

First, the bias generation part 401 generates the first bias BIAS1 having the first reference level REFV1 and the second bias BIAS2 having the second reference level REFV2.

Subsequently, the supply control part 402 checks that the level of the sensing signal SENV is between the level of the first bias BIAS1 and the level of the second bias BIAS2 and outputs a signal SRCON having an enable level according to the check result. For example, the supply control part 402 outputs a signal SRCON having a level relatively close to the first specific level as the level of the sensing signal SENV is relatively close to the level of the second bias BIAS2. Likewise, the supply control part 402 outputs a signal SRCON having a level relatively close to the second specific level as the level of the sensing signal SENV is relatively close to the level of the first bias BIAS1.

Subsequently, the excess control part 404 checks that the level of the sensing signal SENV is lower than the level of the second bias BIAS2 and outputs a transmission control signal DPS of an activated state according to the check result.

Subsequently, the first transmission part 405 transmits the signal SRCON output from the supply control part 402 to the current supply part 403 in response to the transmission control signal DPS, which is in the activated state and output from the excess control part 404.

Subsequently, the second transmission part 406 may not output the disable signal DIS in response to the transmission control signal DPS, which is in the activated state and output from the excess control part 404 (dotted line).

In summary, in response to the fact that the level of the sensing signal SENV is between the level of the first bias BIAS1 having the first reference level REFV1 and the level of the second bias BIAS2 having the second reference level REFV2 (BIAS1<SENV <BIAS2), the signal SRCON having the enable level in the supply control part 402 is transmitted to the current supply part 403 through the first transmission part 405.

Accordingly, the current supply part 403 operates so that current flows between the node of the first power source PV1 and the node of the control power source CONV in response to the output signal SRCON of the supply control part 402 having the enable level. For example, the current supply part 403 may operate so that a relatively small amount of current GI1 flows from the node of the first power source PV1 to the node of the control power source CONV as the level of the signal SRCON output from the supply control part 402 is relatively closer to the second specific level between the first specific level and the second specific level.

Referring to FIG. 4C, when the level of the sensing signal SENV is equal to or higher than the level of the second bias BIAS2 having the second reference level REFV2 (SENV>=BIAS2), the operation of the power supply section 207 can be seen.

First, the bias generation part 401 generates the first bias BIAS1 having the first reference level REFV1 and the second bias BIAS2 having the second reference level REFV2.

Subsequently, the supply control part 402 checks that the level of the sensing signal SENV is equal to or higher than the level of the second bias BIAS2 and outputs a signal SRCON having a disabled level according to the check result.

Subsequently, the excess control part 404 checks that the level of the sensing signal SENV is equal to or higher than the level of the second bias BIAS2 and outputs a transmission control signal DPS in a deactivated state according to the check result.

Subsequently, the first transmission part 405 may not transmit the signal SRCON output from the supply control part 402 to the current supply part 403 in response to the transmission control signal DPS, which is in the deactivated state and output from the excess control part 404.

Subsequently, the second transmission part 406 outputs the disable signal DIS in response to the transmission control signal DPS in the deactivated state and output from the excess control part 404.

In summary, in response to the fact that the level of the sensing signal SENV is equal to or higher than the level of the first bias BIAS1 having the first reference level REFV1 (SENV>=BIAS2), the disable signal DIS is transmitted to the current supply part 403 in response to the transmission control signal DPS in the deactivated state in the excess control part 404. In response to the fact that the level of the sensing signal SENV is equal to or higher than the level of the first bias BIAS1 having the first reference level REFV1 (SENV>=BIAS2), the signal SRCON having the disable level in the supply control part 402 may not be transmitted to the current supply part 403 due to the first transmission part 405.

Accordingly, the current supply part 403 is switched to a disable operation state in response to the disable signal DIS output from the second transmission part 406. That is, the current supply part 403 operates so that no current flows between the node of the first power source PV1 and the node of the control power source CONV in response to the disable signal DIS output from the second transmission part 406.

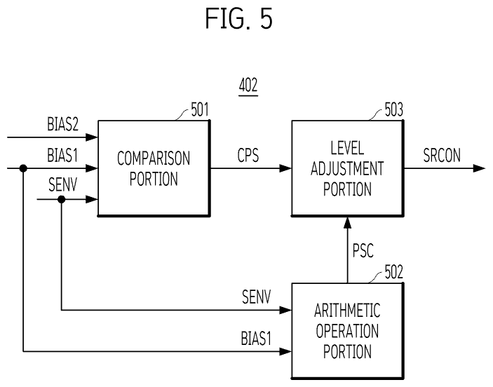

FIG. 5 is a diagram for describing a detailed configuration of the supply control part among components of the power supply section included in the controller in accordance with the first embodiment of the present disclosure.

Referring to FIG. 5, among the components of the power supply section 207 included in the controller 130 in accordance with the first embodiment of the present disclosure, the supply control part 402 includes a comparison portion 501, an arithmetic operation portion 502, and a level adjustment portion 503.

First, the supply control part 402 compares the level of the sensing signal SENV with the level of the first bias BIAS1 and the level of the second bias BIAS2, respectively, and adjusts the level of the signal SRCON to be output in response to the comparison result.

When the level of the sensing signal SENV is equal to or lower than the level of the first bias BIAS1 having the first reference level REFV1, the supply control part 402 outputs a signal SRCON having a disable level.

When the level of the sensing signal SENV is between the level of the first bias BIAS1 having the first reference level REFV1 and the level of the second bias BIAS2 having the second reference level REFV2, the supply control part 402 outputs a signal SRCON having an enable level.

When the level of the sensing signal SENV is equal to or higher than the level of the second bias BIAS2 having the second reference level REFV2, the supply control part 402 outputs a signal SRCON having a disable level.

The comparison portion 501 included in the supply control part 402 compares the level of the sensing signal SENV with the level of the first bias BIAS1 and the level of the second bias BIAS2, respectively, and generates a comparison signal CPS whose activation is determined in response to the comparison result.

According to an embodiment, the comparison portion 501 compares the sensing signal SENV with the first bias BIAS1 and the second bias BIAS2, respectively and outputs a comparison signal CPS of an activated state when the level of the sensing signal SENV is between the first reference level REFV1 and the second reference level REFV2.

According to another embodiment, the comparison portion 501 compares the sensing signal SENV with the first bias BIAS1 and outputs a comparison signal CPS of a deactivated state when the level of the sensing signal SENV is equal to or lower than the first reference level REFV1.

According to further another embodiment, the comparison portion 501 compares the sensing signal SENV with the second bias BIAS2 and outputs a comparison signal CPS of a deactivated state when the level of the sensing signal SENV is equal to or higher than the second reference level REFV2.

The arithmetic operation portion 502 included in the supply control part 402 calculates the level difference between the level of the sensing signal SENV and the first bias BIAS1 having the first reference level REFV1 and output a difference signal PSC.

According to an embodiment, the arithmetic operation portion 502 outputs a difference signal PSC having a relatively large magnitude as the difference between the level of the sensing signal SENV and the first reference level REFV1 is relatively large.

The level adjustment portion 503 included in the supply control part 402 adjusts the level of the signal SRCON to be output according to the length of an activation duration of the comparison signal CPS output from the comparison portion 501 and the magnitude of the difference signal PSC output from the arithmetic operation portion 502. In such a case, the level adjustment portion 503 includes an integration circuit that substitutes the length of the activation duration of the comparison signal CPS as the level of the output signal SRCON and adjusts the level fluctuation range of the output signal SRCON according to the magnitude of the difference signal PSC.

According to an embodiment, the level adjustment portion 503 relatively increases the level of the output signal SRCON as the length of the activation duration of the comparison signal CPS is relatively long.

According to another embodiment, the level adjustment portion 503 relatively decreases the level of the output signal SRCON as the length of a deactivation duration of the comparison signal CPS is relatively long.

According to further another embodiment, the level adjustment portion 503 relatively increases the level fluctuation range, that is, the increase or decrease range, of the output signal SRCON as the magnitude of the difference signal PSC, is relatively large.

According to yet another embodiment, the level adjustment portion 503 relatively decreases the level fluctuation range, that is, the increase or decrease range, of the output signal SRCON as the magnitude of the difference signal PSC is relatively small.

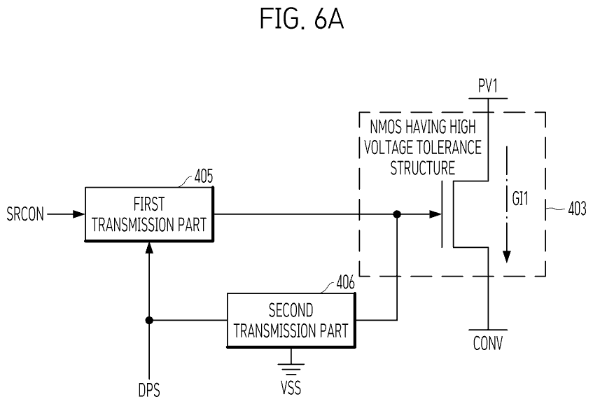

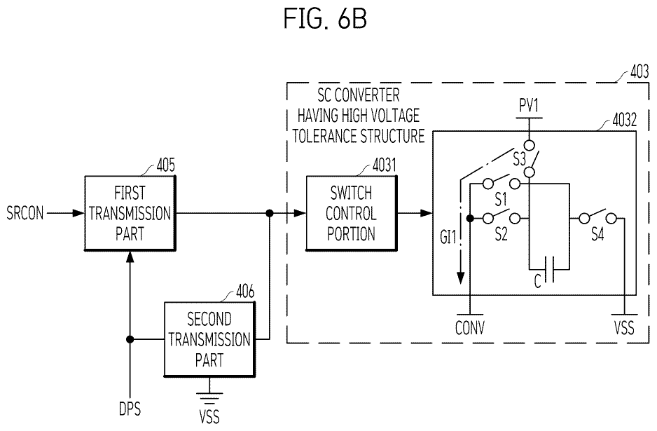

FIGS. 6A and 6B are diagrams for describing a detailed configuration of the current supply part among the components of the power supply section included in the controller in accordance with the first embodiment of the present disclosure.

First, referring to FIG. 6A, among the components of the power supply section 207 included in the controller 130 in accordance with the first embodiment of the present disclosure, the current supply part 403 includes an NMOS transistor having a high voltage tolerance structure.

Specifically, the NMOS transistor included in the current supply part 403 and having a high voltage tolerance structure adjusts the amount of current flowing from a drain thereof connected to the node of the first power source PV1 to a source thereof connected to the node of the control power source CONV, according to the level of a signal applied to a gate thereof, that is, a signal transmitted through the first transmission part 405.

The NMOS transistor having high voltage tolerance has a relatively longer physical distance between the drain and the source compared to an NMOS transistor having no high voltage tolerance. In this way, when the physical distance between the drain and the source is relatively long, an electric field is prevented from being concentrated at a specific point and destroying the transistor.

In addition, the NMOS transistor having high voltage tolerance has more high resistance drift regions inserted between the drain and the source compared to an NMOS transistor having no high voltage tolerance. In this way, when the high resistance drift region is inserted between the drain and the source, the concentration of an electric field is distributed, so that the high voltage tolerance of the transistor is increased.

In addition, the NMOS transistor having high voltage tolerance has a relatively thicker gate oxide film compared to an NMOS transistor having no high voltage tolerance. In this way, when the transistor has the thick gate oxide film, the gate oxide film is prevented from being destroyed by high voltage.

In addition, the NMOS transistor having high voltage tolerance maintains a body (Bulk) in a floating state without connecting the body to specific voltage, compared to an NMOS transistor having no high voltage tolerance. In this way, by maintaining the body in a floating state, voltage applied between the drain and the source is distributed.

In addition, the NMOS transistor having high voltage tolerance extends the length of the drain, compared to an NMOS transistor having no high voltage tolerance. In this way, by extending the length of the drain, an electric field concentration occurring when high voltage current flows, is effectively distributed.

On the other hand, as illustrated in FIG. 6A, when the current supply part 403 includes the NMOS transistor having a high voltage tolerance structure, the signal SRCON having a disable level that is transmitted through the first transmission part 405 is a signal SRCON having a ground voltage level (VSS).

Likewise, when the current supply part 403 includes the NMOS transistor having a high voltage tolerance structure as illustrated in FIG. 6A, the disable signal DIS that is transmitted through the second transmission part 406 is a signal having the ground voltage level (VSS).

Referring to FIG. 6B, among the components of the power supply section 207 included in the controller 130 in accordance with the first embodiment of the present disclosure, the current supply part 403 includes a switched-capacitor (SC) converter circuit having a high voltage tolerance structure.

Specifically, the switched-capacitor converter circuit included in the current supply part 403 and having a high voltage tolerance structure includes a switch control portion 4031 and a supply operation portion 4032.

The switch control portion 4031 generates a signal for controlling operations of the switch elements S1 to S4 included in the supply operation portion 4032 according to the level of a signal transmitted through the first transmission part 405.

The supply operation portion 4032 adjusts the amount of current flowing from the node of the first power source PV1 to the node of the control power source CONV through an operation of charging and discharging a capacitor element C connected between the node of the first power source PV1 and the node of the control power source CONV by turning on/off the switch elements S1 to S4 included therein in response to the signal output from the switch control portion 4031.

More specifically, the switch control portion 4031 supplies current from the node of the first power source PV1 to the node of the control power source CONV by alternately performing an operation of charging the capacitor element C by transmitting a signal for turning off the first, second, and fourth switch elements S1, S2, and S4 and turning on the third switch element S3 to the supply operation portion 4032 in response to the fact that the signal SRCON output from the supply control part 402 is at an enable level, and an operation of discharging the capacitor element C by transmitting a signal for turning off the first and second switch elements S1 and S2 and turning off the third and fourth switch elements S3 and S4 to the supply operation portion 4032. In such a case, the switch control portion 4031 operates so that a relatively large amount of current GI1 flows from the node of the first power source PV1 to the node of the control power source CONV by charging and discharging the capacitor element C included in the supply operation portion 4032 at a relatively higher speed as the level of the signal SRCON output from the supply control part 402 is relatively closer to the first specific level between the first specific level and the second specific level.

In addition, the switch control portion 4031 transmits a signal for turning off the first, second, and third switch elements S1 to S3 and turning on the fourth switch element S4 to the supply operation portion 4032 in response to the fact that the signal SRCON output from the supply control part 402 is at a disable level, thereby preventing the capacitor element C from being charged and discharged and at the same time, thereby allowing the node of the first power source PV1 and the node of the control power source CONV to be insulated.

On the other hand, the switch-capacitor converter circuit having high voltage tolerance has a relatively higher rated voltage than a switch-capacitor converter circuit having no high voltage tolerance because the capacitor element C included therein has a relatively thicker insulation layer.

In addition, in the switch-capacitor converter circuit having high voltage tolerance, the switch elements S1 to S4 included therein are high voltage transistors such as high voltage MOSFETs or IGBTs, compared to a switch-capacitor converter circuit having no high voltage tolerance.

In such a case, in the switch elements S1 to S4 having high voltage tolerance, a physical distance between a drain and a source of the transistor is relatively long, compared to switch elements S1 to S4 having no high voltage tolerance. In this way, when the physical distance between the drain and source of the transistor is relatively long, an electric field is prevented from being concentrated at a specific point and destroying the switch element S1 to S4.

In addition, the switch element S1 to S4 with high voltage tolerance have more high resistance drift regions inserted between the drain and source of the transistor compared to switch element S1 to S4 having no high voltage tolerance. In this way, when the high resistance drift region is inserted between the drain and source of the transistor, the concentration of an electric field is distributed, so that the high voltage tolerance of the switch element S1 to S4 is increased.

In addition, the switch elements S1 to S4 having high voltage tolerance have a relatively thicker gate oxide film of the transistor compared to switch elements S1 to S4 having no high voltage tolerance. In this way, when the transistor has a thick gate oxide film, the gate oxide film is prevented from being destroyed by high voltage.

In addition, the switch elements S1 to S4 having high voltage tolerance maintain a body (Bulk) of the transistor in a floating state without connecting the body to a specific voltage, compared to switch elements S1 to S4 having no high voltage tolerance. In this way, by maintaining the body in a floating state, voltage applied between the drain and source of the transistor is distributed.

In addition, the switch elements S1 to S4 having high voltage tolerance extend the length of the drain in the transistor compared to switch elements S1 to S4 having no high voltage tolerance. In this way, by extending the length of the drain, an electric field concentration occurring when high voltage current flows, is effectively distributed.

### Second Embodiment

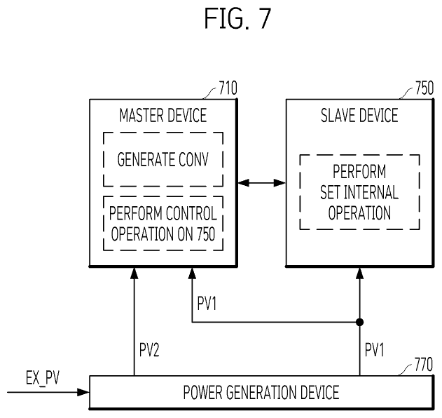

FIG. 7 is a diagram for describing an electronic apparatus including a master device and a slave device in accordance with a second embodiment of the present disclosure.

Referring to FIG. 7, an electronic apparatus in accordance with the second embodiment of the present disclosure includes a master device 710, a slave device 750, and a power generation device 770.

First, the electronic apparatus is mounted with electronic components including an integrated circuit for performing various functions. The mounted electronic components are connected to a serial bus and transmit various types of data. A controller controlling the electronic apparatus transmits data to specific components or receive data from the specific components by using unique addresses of the components connected to the serial bus.

The master device 710 is a device capable of controlling one or more slave devices 750 and is a controller of the electronic apparatus. FIG. 7 illustrates only one slave device 750, but this is merely one embodiment, and actually, one or more slave devices 750 can be connected in parallel to the master device 710.

According to an embodiment, when the electronic apparatus is the memory system 110 (see FIGS. 1A and 1B), the master device 710 is the controller 130 (see FIGS. 1A and 1B), and the slave device 750 is the memory device 150 (see FIGS. 1A and 1B).

Specifically, the power generation device 770 generates power PV1 and PV2 used for the operation of the electronic apparatus.

In addition, the power generation device 770 receives an external power source EX_PV and generates a first power source PV1 having a first voltage level and a second power source PV2 having a second voltage level lower than the first voltage level. According to an embodiment, the first voltage level is a 2.5 V level, and the second voltage level is a 1.2 V level.

In addition, the power generation device 770 sets the maximum current amount of the first power source PV1 and the maximum current amount of the second power source PV2, respectively. According to an embodiment, the maximum current amount of the first power source PV1 is 2000 mA, and the maximum current amount of the second power source PV2 is 2000 mA.

Specifically, the slave device 750 operates a set internal operation by using the first power source PV1 supplied from the power generation device 770. That is, to perform the set internal operation under the control of the master device 710, the slave device 750 uses the first power source PV1 supplied from the power generation device 770.

The master device 710 performs a control operation for controlling the set internal operation performed in the slave device 750. In addition, the master device 710 uses an internally generated control power source CONV in order to perform the control operation.

When the present current amount of the internally generated control power source CONV is equal to or less than a first current amount, the master device 710 receives the second power source PV2 generated by the power generation device 770 to generate the control power source CONV, and then perform the control operation by using the generated control power source CONV. That is, when the present current amount of the control power source CONV is equal to or less than the first current amount, the master device 710 generates the control power source CONV by using only the current supplied from the second power source PV2.

When the present current amount of the internally generated control power source CONV exceeds the first current amount, the master device 710 simultaneously receives the first power source PV1 and the second power source PV2 generated by the power generation device 770 to generate the control power source CONV, and then perform the control operation by using the generated control power source CONV. That is, when the present current amount of the control power source CONV exceeds the first current amount, the master device 710 not only generates the control power source CONV by using the current supplied from the second power source PV2, but also supplies the current of the control power source CONV by using the current supplied from the first power source PV1 at the same time.

In such a case, the master device 710 predefines the maximum amount of current suppliable from the first power source PV1 to the control power source CONV. That is, since the slave device 750 receives the first power source PV1 and performs a set internal operation, the master device 710 defines the maximum amount of current suppliable from the first power source PV1 to the control power source CONV as an amount that does not affect the set internal operation performed in the slave device 750. For example, in FIG. 7, the maximum amount of current of the first power source PV1 is 2000 mA and the amount that does not affect the set internal operation performed in the slave device 750 is 1700 mA. Accordingly, the master device 710 defines the maximum amount of current suppliable from the first power source PV1 to the control power source CONV as an amount of 300 mA.

The voltage level of the control power source CONV has a voltage level lower than the second voltage level, for example, a 0.75 V level.

The control operation performed by the master device 710 includes a plurality of sub-control operations.

The control operation performed by the master device 710 is adjusted in various ways depending on the type of electronic apparatus and the designer's selection. In addition, depending on the type of the control operation performed by the master device 710, the plurality of sub-control operations included in the control operation is classified into various forms. For example, when the control operation performed by the master device 710 is an operation for controlling a program operation of the slave device 750, the plurality of sub-control operations may include an operation for transmitting a program command, program data, and an address by referring to mapping information, an operation for setting a program voltage level, an operation for transmitting program data, an operation for checking whether the program operation is successful, and the like.

When the present current amount of the internally generated control power source CONV is equal to or greater than a second current amount greater than the first current amount, the master device 710 reduces the present current amount of the control power source CONV by stopping the M number of sub-control operations among the N number of sub-control operations being performed or scheduled to be performed, the control operation including the N number of sub-control operations. Here, N is a natural number equal to or greater than 1, and M is a natural number equal to or greater than 1 and equal to or less than N.

In such a case, the master device 710 adjusts the value of M so that the present current amount of the control power source CONV, which is reduced in amount by stopping the M number of sub-control operations among the N number of sub-control operations being performed or scheduled to be performed, is equal to or less than the first current amount, the control operation including the N number of sub-control operations.

According to an embodiment, in a case where the present current amount of the internally generated control power source CONV is equal to or greater than the second current amount greater than the first current amount and the present current amount of the control power source CONV is predicted to be reduced to be equal to or less than the first current amount when stopping all of the N number of sub-control operations being performed or scheduled to be performed, the master device 710 stops all of the N number of sub-control operations being performed or scheduled to be performed by setting the value of M to be identical to the value of N, the control operation including the N number of sub-control operations.

According to another embodiment, in a case where the present current amount of the internally generated control power source CONV is equal to or greater than the second current amount greater than the first current amount and the present current amount of the control power source CONV is predicted to be reduced to be equal to or less than the first current amount when stopping some of the N number of sub-control operations being performed or scheduled to be performed, the master device 710 selectively stops only the M number of sub-control operations being a part of the N number of sub-control operations being performed or scheduled to be performed by setting the value of M to be less than the value of N, the control operation including the N number of sub-control operations.

The master device 710 includes information on the amount of current expected to be consumed by each of the plurality of sub-control operations included in the control operation. The amount of current expected to be consumed by each of the plurality of sub-control operations is determined through a test performed in advance during a process of producing the electronic apparatus including the master device 710.

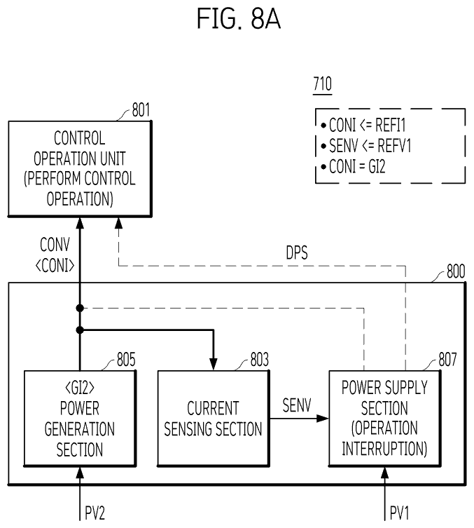

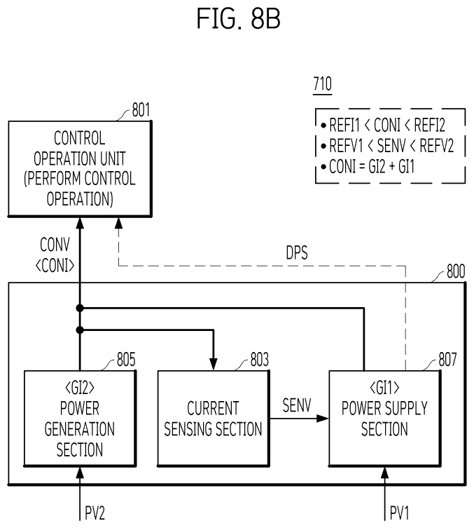

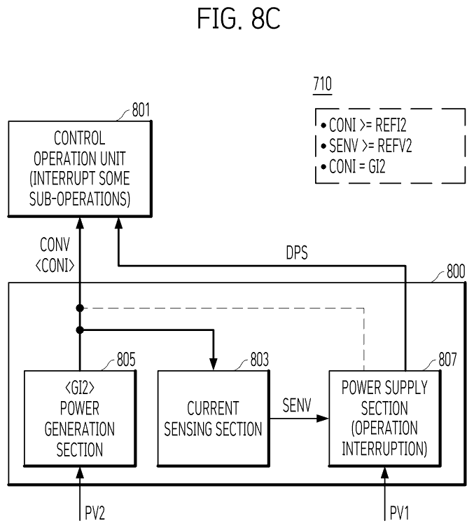

FIGS. 8A to 8C are diagrams for describing an operation in which the master device in accordance with the second embodiment of the present disclosure generates a control power source.

Referring to FIGS. 8A to 8C, the power management unit 800 included in the master device 710 in accordance with the second embodiment of the present disclosure includes a current sensing section 803, a power generation section 805, and a power supply section 807.

First, when the present current amount of the control power source CONV is equal to or less than the first current amount, the power management unit 800 generates the control power source CONV by receiving the second power source PV2 generated by the power generation device 770 (see FIG. 7).

In addition, when the present current amount of the control power source CONV exceeds the first current amount, the power management unit 800 generates the control power source CONV by simultaneously receiving the first power source PV1 and the second power source PV2 generated by the power generation device 770.

In addition, when the present current amount of the control power source CONV is equal to or greater than the second current amount greater than the first current amount, the power management unit 800 requests (DPS) a control operation section 801 to perform an operation for reducing the present current amount of the control power source CONV.

Specifically, the current sensing section 803 included in the power management unit 800 senses the present current amount of the control power source CONV. That is, the current sensing section 803 generates a sensing signal SENV whose level is adjusted according to the present current amount of the control power source CONV.

When a present current amount CONI of the control power source CONV is equal to or less than a first current amount REFI1 (CONI<=REFI1), the current sensing section 803 generates a sensing signal SENV having a level equal to or lower than a first reference level REFV1.

When the present current amount CONI of the control power source CONV is equal to or greater than a second current amount REFI2 (CONI>=REFI2), the current sensing section 803 generates a sensing signal SENV having a level equal to or higher than a second reference level REFV2.

When the present current amount CONI of the control power source CONV is between the first and second current amounts REFI1 and REFI2 (REFI1<CONI<REFI2), the current sensing section 803 generates the sensing signal SENV having a level set between the first and second reference levels REFV1 and REFV2.

The power generation section 805 included in the power management unit 800 generates the control power source CONV by receiving the second power source PV2. That is, when the second power source PV2 is supplied from the outside for the operation of the master device 710, the power generation section 805 generates the control power source CONV in response to the supply of the second power source PV2. In such a case, the power generation section 805 supplies current GI2 from a node of the second power source PV2 to the node of the control power source CONV through the operation of generating the control power source CONV by receiving the second power source PV2. For example, the power generation section 805 may supply the current GI2 of up to 2000 mA from the node of the second power source PV2 to the node of the control power source CONV through the operation of generating the control power source CONV by receiving the second power source PV2.

According to an embodiment, the power generation section 805 operates in an LDO (Low Dropout Regulator) mode, that is, a low-voltage differential linear voltage regulator mode. For example, the power generation section 805 may receive the second power source PV2 at a 1.2 V level and operate in the LDO mode to generate the control power source CONV at a 0.75 V level.

The power supply section 807 included in the power management unit 800 adjusts the amount of a current GI1 supplied from the node of the first power source PV1 to the node of the control power source CONV in response to the output signal SENV of the current sensing section 803. That is, the power supply section 807 adjusts the amount of the current GI1 supplied from the node of the first power source PV1 to the node of the control power source CONV according to the level of the sensing signal SENV output from the current sensing section 803. In such a case, the power supply section 807 only performs an operation of adjusting the amount of the current GI1 supplied from the node of the first power source PV1 to the node of the control power source CONV, and may not perform an operation of directly generating the control power source CONV like the power generation section 805, that is, regulating to maintain the voltage level (for example, 0.75 V level) of the control power source CONV.

The power supply section 807 supplies the current GI1 from the node of the first power source PV1 to the node of the control power source CONV in a duration where the level of the sensing signal SENV output from the current sensing section 803 is between the first and second reference levels REFV1 and REFV2.

In addition, the power supply section 807 supplies no current from the node of the first power source PV1 to the node of the control power source CONV in a duration where the level of the sensing signal SENV output from the current sensing section 803 is equal to or lower than the first reference level REFV1. That is, the power supply section 807 stops the operation of supplying current in a duration where the sensing signal SENV output from the current sensing section 803 is equal to or lower than the first reference level REFV1.

In addition, the power supply section 807 supplies no current from the node of the first power source PV1 to the node of the control power source CONV in a duration where the level of the sensing signal SENV output from the current sensing section 803 is equal to or higher than the second reference level REFV2. That is, the power supply section 807 stops the operation of supplying current in a duration where the sensing signal SENV output from the current sensing section 803 is equal to or higher than the second reference level REFV2. In addition, in response to the fact that the level of the sensing signal SENV output from the current sensing section 803 is equal to or higher than the second reference level REFV2, the power supply section 807 requests (DPS) the control operation section 801 to perform the operation for reducing the present current amount of the control power source CONV.

According to an embodiment, the power supply section 807 includes a dependent current source (DCS) circuit. That is, the power supply section 807 includes a dependent current source circuit for adjusting the amount of the current GI1 flowing from the node of the first power source PV1 to the node of the control power source CONV by adjusting an operation of a switch element included therein according to the level of the sensing signal SENV and thus controlling the charging and discharging of a capacitor element connected between the node of the first power source PV1 and the node of the control power source CONV.

According to another embodiment, the power supply section 807 includes a switched-capacitor (SC) converter circuit. That is, the power supply section 807 includes a switched-capacitor converter circuit for adjusting the amount of the current GI1 flowing between the node of the first power source PV1 and the node of the control power source CONV according to the level of the sensing signal SENV.

Referring to FIG. 8A, when the present current amount of the control power source CONV is equal to or less than the first current amount REFI1 (CONI<=REFI1), the operation of the power management unit 800 can be seen.

First, in FIG. 8A, the second power source PV2 is supplied, and the power generation section 805 generates the control power source CONV by receiving the second power source PV2. That is, the power generation section 805 supplies the current GI2 from the node of the second power source PV2 to the node of the control power source CONV.

The current sensing section 803 detects that the present current amount CONI of the control power source CONV is equal to or less than the first current amount REFI1 (CONI<=REFI1), and sets the level of the sensing signal SENV to a level equal to or lower than the first reference level REFV1 (SENV<=REFV1).

When the present current amount CONI of the control power source CONV is equal to or less than the first current amount REFI1 (SENV<=REFV1), it means that the current amount of the control power source CONV required for the control operation section 801 to perform the control operation is less than the maximum current amount suppliable through the second power source PV2. That is, it means that the control operation section 801 can perform the control operation even in a state where no current is supplied from the node of the first power source PV1 to the node of the control power source CONV through the power supply section 807.

Accordingly, the power supply section 807 may not perform an operation of supplying current in response to the sensing signal SENV having a level equal to or lower than the first reference level REFV1 (SENV<=REFV1) (operation interruption). That is, the power supply section 807 prevents current from flowing between the node of the first power source PV1 and the node of the control power source CONV in response to the sensing signal SENV having a level equal to or lower than the first reference level REFV1 (SENV<=REFV1).

In summary, in a state like FIG. 8A, that is, the power generation section 805 performs an operation of generating the control power source CONV and supplies the current GI2 from the node of the second power source PV2 to the node of the control power source CONV, but since the power supply section 807 is in a state of ‘operation interruption’ and supplies no current to the node of the control power source CONV, the present current amount CONI of the control power source CONV is identical to the current GI2 supplied to the node of the control power source CONV through the power generation section 805 (CONI=GI2).

Referring to FIG. 8B, when the present current amount of the control power source CONV is between the first and second current amounts REFI1 and REFI2 (REFI1<CONI<REFI2), the operation of the power management unit 800 can be seen.

First, in FIG. 8B, the second power source PV2 is supplied, and the power generation section 805 generates the control power source CONV by receiving the second power source PV2. That is, the power generation section 805 supplies the current GI2 from the node of the second power source PV2 to the node of the control power source CONV.

The current sensing section 803 detects that the present current amount CONI of the control power source CONV is between the first and second current amounts REFI1 and REFI2 (REFI1<CONI<REFI2), and sets the level of the sensing signal SENV to a level between the first and second reference levels REFV1 and REFV2 (REFV1<SENV<REFV2).

When the present current amount CONI of the control power source CONV is between the first and second current amounts REFI1 and REFI2 (REFI1<CONI<REFI2), it means that the current amount of the control power source CONV required for the control operation section 801 to perform the control operation is greater than the maximum current amount suppliable through the second power source PV2. That is, it can be seen that only when the power management unit 800 generates the control power source CONV by receiving both the current of the second power source PV2 and the current of the first power source PV1, the control operation section 801 normally performs the control operation by using the control power source CONV.

Accordingly, the power supply section 807 performs an operation of supplying current in response to the sensing signal SENV having a level between the first and second reference levels REFV1 and REFV2 (REFV1<SENV<REFV2). That is, the power supply section 807 supplies the current GI1 from the node of the first power source PV1 to the node of the control power source CONV in response to the sensing signal SENV having a level between the first and second reference levels REFV1 and REFV2 (REFV1<SENV<REFV2).

In summary, in a state like FIG. 8B, that is, in a state where the power generation section 805 supplies the current GI2 from the node of the second power source PV2 to the node of the control power source CONV by performing an operation of generating the control power source CONV and the power supply section 807 also performs an operation of supplying the current GI1 from the node of the first power source PV1 to the node of the control power source CONV, the present current amount CONI of the control power source CONV is the sum (CONI=GI2+GI1) of the current GI2 supplied to the node of the control power source CONV through the power generation section 805 and the current GI1 supplied to the node of the control power source CONV through the power supply section 807.

Referring to FIG. 8C, when the present current amount of the control power source CONV is equal to or greater than the second current amount REFI2 (CONI>=REFI2), the operation of the power management unit 800 can be seen.

First, in FIG. 8C, the second power source PV2 is supplied, and the power generation section 805 generates the control power source CONV by receiving the second power source PV2. That is, the power generation section 805 supplies the current GI2 from the node of the second power source PV2 to the node of the control power source CONV.

The current sensing section 803 detects that the present current amount CONI of the control power source CONV is equal to or greater than the second current amount REFI2 (CONI>=REFI2), and sets the level of the sensing signal SENV to a level equal to or higher than the second reference level REFV2 (SENV>=REFV2).

When the present current amount CONI of the control power source CONV is equal to or greater than the second current amount REFI2 (SENV>=REFV2), it means that the current amount of the control power source CONV required for the control operation section 801 to perform the control operation is greater than the sum of the maximum current amount suppliable through the second power source PV2 and the maximum current amount suppliable through the first power source PV1. That is, it means that even though the current GI2 is supplied from the node of the second power source PV2 to the node of the control power source CONV through the power generation section 805 at a maximum amount (for example, 2000 mA) and at the same time, the current GI1 is supplied from the node of the first power source PV1 to the node of the control power source CONV through the power supply section 807 at a maximum amount (for example, 300 mA), it is less than the current amount of the control power source CONV required by the control operation section 801.

Therefore, when the present current amount CONI of the control power source CONV is equal to or greater than the second current amount REFI2 (SENV>=REFV2), the power supply section 807 requests (DPS) the control operation section 801 to perform an operation for reducing the present current amount of the control power source CONV. In addition, when the present current amount CONI of the control power source CONV is equal to or greater than the second current amount (SENV>=REFV2), the power supply section 807 stops the operation of receiving the current GI1 from the first power source PV1, which has been started to be performed when the present current amount of the control power source CONV is less than the second current amount REFI2 (operation stop). Of course, since the power generation section 805 continues to operate regardless of the interruption of the operation of the power supply section 807, the current GI2 is continuously supplied from the node of the second power source PV2 to the node of the control power source CONV.

In such a case, the control operation section 801 reduces the present current amount of the control power source CONV by interrupting the M number of sub-control operations among the N number of sub-control operations being performed or scheduled to be performed, in response to the request (DPS) of the power supply section 807 (interrupting some sub-operations), the control operation including the N number of sub-control operations. Here, N is a natural number equal to or greater than 1, and M is a natural number equal to or greater than 1 and equal to or less than N. In addition, the control operation section 801 predicts the current amount of the control power source CONV that is reduced in amount by stopping the M number of sub-control operations among the N number of sub-control operations being performed or scheduled to be performed in response to the request (DPS) of the power supply section 807, and adjusts the value of M so that the present current amount of the control power source CONV becomes equal to or less than the first current amount according to the predicted result, the control operation including the N number of sub-control operations.

In summary, in a state like FIG. 8C, that is, the power generation section 805 performs an operation of generating the control power source CONV and supplies the current GI2 from the node of the second power source PV2 to the node of the control power source CONV, but since the power supply section 807 is in a state of ‘operation interruption’ and supplies no current to the node of the control power source CONV, the present current amount CONI of the control power source CONV is identical to the current GI2 supplied to the node of the control power source CONV through the power generation section 805 (CONI=GI2).

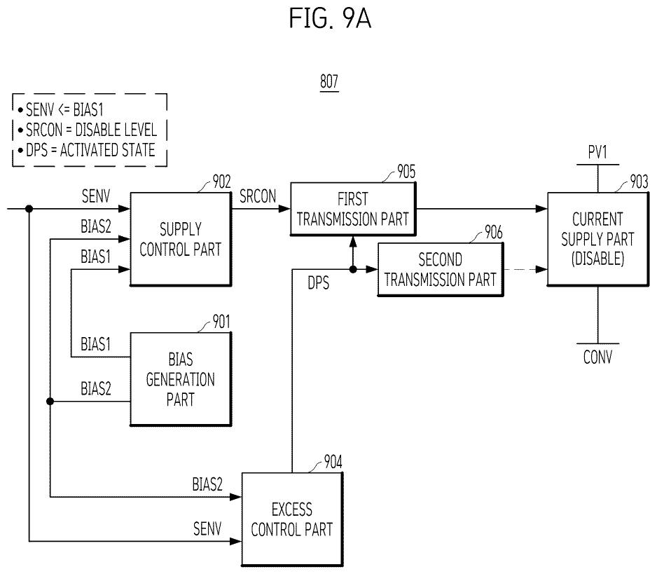

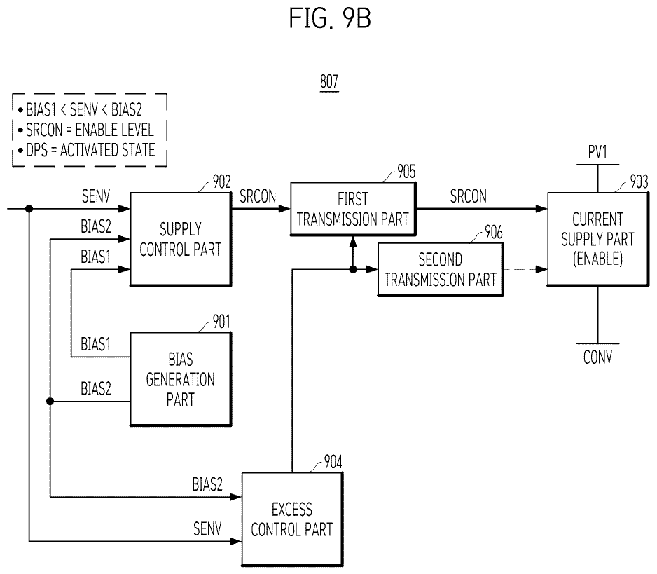

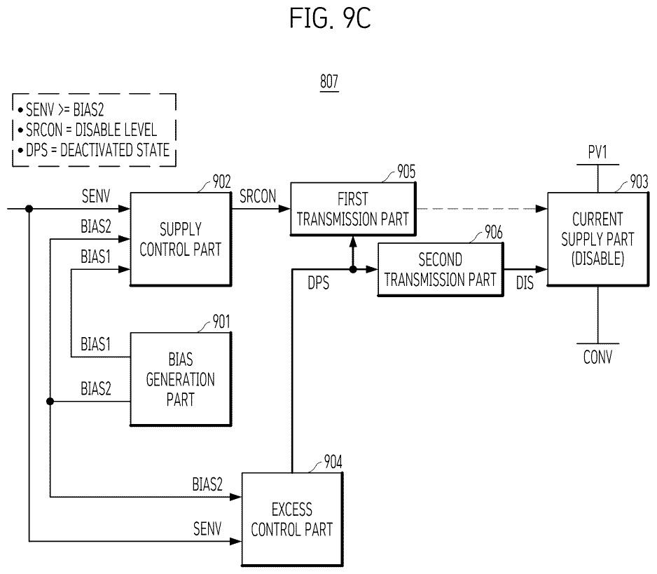

FIGS. 9A to 9C are diagrams for describing an operation in which the power supply section included in the master device in accordance with the second embodiment of the present disclosure supplies a current.

Referring to FIGS. 9A to 9C, the power supply section 807 included in the master device 710 in accordance with the second embodiment of the present disclosure includes a bias generation part 901, a supply control part 902, a current supply part 903, an excess control part 904, a first transmission part 905, and a second transmission part 906.

First, the power supply section 807 adjusts the amount of the current GI1 supplied from the node of the first power source PV1 to the node of the control power source CONV according to the level of the sensing signal SENV output from the current sensing section 803.

In addition, the power supply section 807 supplies the current GI1 from the node of the first power source PV1 to the node of the control power source CONV in a duration where the level of the sensing signal SENV output from the current sensing section 803 is between the first and second reference levels REFV1 and REFV2.

In addition, the power supply section 807 supplies no current from the node of the first power source PV1 to the node of the control power source CONV in a duration where the level of the sensing signal SENV output from the current sensing section 803 is equal to or lower than the first reference level REFV1.

In addition, the power supply section 807 supplies no current from the node of the first power source PV1 to the node of the control power source CONV in a duration where the level of the sensing signal SENV output from the current sensing section 803 is equal to or higher than the second reference level REFV2.

That is, the power supply section 807 stops the operation of supplying current in a duration where the level of the sensing signal SENV output from the current sensing section 803 is equal to or lower than the first reference level REFV1 or in a duration where the level of the sensing signal SENV output from the current sensing section 803 is equal to or higher than the second reference level REFV2.

In addition, the power supply section 807 requests (DPS) the control operation section 801 to perform an operation for reducing the present current amount of the control power source CONV in response to the present current amount CONI of the control power source CONV being equal to or greater than the second current amount REFI2 (SENV>=REFV2).

The bias generation part 901 included in the power supply section 807 generates a first bias BIAS1 having the first reference level REFV1 and a second bias BIAS2 having the second reference level REFV2.

The supply control part 902 included in the power supply section 807 compares the level of the sensing signal SENV with the level of the first bias BIAS1 and the level of the second bias BIAS2, respectively, and adjusts a level of a signal SRCON output in response to the comparison result.

According to an embodiment, when the level of the sensing signal SENV is equal to or lower than the level of the first bias BIAS1 having the first reference level REFV1, the supply control part 902 outputs the signal SRCON having a level (hereinafter, referred to as a “disable level”) that may disable the flow of current from the node of the first power source PV1 to the node of the control power source CONV.

According to another embodiment, when the level of the sensing signal SENV is between the level of the first bias BIAS1 having the first reference level REFV1 and the level of the second bias BIAS2 having the second reference level REFV2, the supply control part 902 outputs the signal SRCON having a level (hereinafter, referred to as an ‘enable level’) that may enable current to flow from the node of the first power source PV1 to the node of the control power source CONV. The enable level is determined between a first specific level and a second specific level that are set in advance. For example, in response to the output signal SRCON being having the first specific level, the amount of the current flowing between the node of the first power source PV1 and the node of the control power source CONV is relatively greater than the amount of the current flowing between the node of the first power source PV1 and the node of the control power source CONV in response to the output signal SRCON being having the second specific level.

According to further another embodiment, when the level of the sensing signal SENV is equal to or higher than the level of the second bias BIAS2 having the second reference level REFV2, the supply control part 902 outputs the signal SRCON having the disable level.

The current supply part 903 included in the power supply section 807 supplies the current GI1 having an amount corresponding to the level of the signal SRCON output from the supply control part 902 from the node of the first power source PV1 to the node of the control power source CONV.

According to an embodiment, the current supply part 903 operates so that no current flows between the node of the first power source PV1 and the node of the control power source CONV in response to the fact that the signal SRCON output from the supply control part 902 is at a disable level. In this way, the operation of the current supply part 903 that prevents current from flowing between the node of the first power source PV1 and the node of the control power source CONV is referred to as a ‘disable operation’.

According to another embodiment, the current supply part 903 operates to allow the current GI1 to flow from the node of the first power source PV1 to the node of the control power source CONV in response to the fact that the signal SRCON output from the supply control part 902 is at an enable level. In this way, the operation of the current supply part 903 that allows current to flow between the node of the first power source PV1 and the node of the control power source CONV is referred to as an ‘enable operation’. For example, the current supply part 903 may operate to allow a relatively large amount of current GI1 to flow from the node of the first power source PV1 to the node of the control power source CONV as the level of the signal SRCON output from the supply control part 902 is relatively closer to the first specific level between the first specific level and the second specific level.

The excess control part 904 included in the power supply section 807 compares the level of the sensing signal SENV with the level of the second bias BIAS2 and outputs a transmission control signal DPS staying deactivated while the level of the sensing signal SENV is equal to or higher than the second reference level REFV2. In addition, the excess control part 904 compares the level of the sensing signal SENV with the level of the second bias BIAS2 and outputs a transmission control signal DPS staying activated while the level of the sensing signal SENV is lower than the second reference level REFV2.

The first transmission part 905 included in the power supply section 807 transmits the signal SRCON output from the supply control part 902 to the current supply part 903 in a duration where the transmission control signal DPS output from the excess control part 904 is activated. In addition, the first transmission part 905 may not transmit the signal SRCON output from the supply control part 902 to the current supply part 903 in a duration where the transmission control signal DPS output from the excess control part 904 is deactivated.

The second transmission part 906 included in the power supply section 807 outputs a disable signal DIS for switching the current supply part 903 to a disabled operation state in the duration where the transmission control signal DPS output from the excess control part 904 is deactivated. In addition, the second transmission part 906 may not output the disable signal DIS for switching the current supply part 903 to the disabled operation state in the duration where the transmission control signal DPS output from the excess control part 904 is activated.

On the other hand, the operation of transitioning the transmission control signal DPS output from the excess control part 904 from an activated state to a deactivated state is an operation of the power supply section 807 requesting the control operation section 801 to perform an operation for reducing the present current amount of the control power source CONV. That is, the control operation section 801 reduces the present current amount of the control power source CONV by stopping the M number of sub-control operations among the N number of sub-control operations being performed or scheduled to be performed in response to the fact that the transmission control signal DPS output from the excess control part 904 included in the power supply section 807 transitions from an activated state to a deactivated state, the control operation including the N number of sub-control operations.

Referring to FIG. 9A, when the level of the sensing signal SENV is equal to or lower than the level of the first bias BIAS1 having the first reference level REFV1 (SENV<=BIAS1), the operation of the power supply section 807 can be seen.

First, the bias generation part 901 generates the first bias BIAS1 having the first reference level REFV1 and the second bias BIAS2 having the second reference level REFV2.

Subsequently, the supply control part 902 checks that the level of the sensing signal SENV is equal to or lower than the level of the first bias BIAS1 and outputs a signal SRCON having a disable level according to the check result.

Subsequently, the excess control part 904 checks that the level of the sensing signal SENV is lower than the level of the second bias BIAS2 and outputs a transmission control signal DPS of an activated state according to the check result.

Subsequently, the first transmission part 905 transmits the signal SRCON output from the supply control part 902 to the current supply part 903 in response to the transmission control signal DPS, which is in the activated state and output from the excess control part 404.

Subsequently, the second transmission part 906 may not output the disable signal DIS in response to the transmission control signal DPS, which is in the activated state and output from the excess control part 904 (dotted line).

In summary, in response to the fact that the level of the sensing signal SENV is equal to or lower than the level of the first bias BIAS1 having the first reference level REFV1 (SENV<=BIAS1), the signal SRCON having the disable level in the supply control part 902 is transmitted to the current supply part 903 through the first transmission part 905.

Accordingly, the current supply part 903 operates so that no current flows between the node of the first power source PV1 and the node of the control power source CONV in response to the output signal SRCON of the supply control part 902 having the disable level.

Referring to FIG. 9B, when the level of the sensing signal SENV is between the level of the first bias BIAS1 having the first reference level REFV1 and the level of the second bias BIAS2 having the second reference level REFV2 (BIAS1<SENV<BIAS2), the operation of the power supply section 807 can be seen.

First, the bias generation part 901 generates the first bias BIAS1 having the first reference level REFV1 and the second bias BIAS2 having the second reference level REFV2.

Subsequently, the supply control part 902 checks that the level of the sensing signal SENV is between the level of the first bias BIAS1 and the level of the second bias BIAS2 and outputs a signal SRCON having an enable level according to the check result. For example, the supply control part 902 outputs a signal SRCON having a level relatively close to the first specific level as the level of the sensing signal SENV is relatively close to the level of the second bias BIAS2. Likewise, the supply control part 902 outputs a signal SRCON having a level relatively close to the second specific level as the level of the sensing signal SENV is relatively close to the level of the first bias BIAS1.

Subsequently, the excess control part 904 checks that the level of the sensing signal SENV is lower than the level of the second bias BIAS2 and outputs a transmission control signal DPS of an activated state according to the check result.

Subsequently, the first transmission part 905 transmits the signal SRCON output from the supply control part 902 to the current supply part 903 in response to the transmission control signal DPS, which is in the activated state and output from the excess control part 404.

Subsequently, the second transmission part 906 may not output the disable signal DIS in response to the transmission control signal DPS, which is in the activated state and output from the excess control part 904 (dotted line).

In summary, in response to the fact that the level of the sensing signal SENV is between the level of the first bias BIAS1 having the first reference level REFV1 and the level of the second bias BIAS2 having the second reference level REFV2 (BIAS1<SENV<BIAS2), the signal SRCON having the enable level in the supply control part 902 is transmitted to the current supply part 903 through the first transmission part 905.

Accordingly, the current supply part 903 operates so that current flows between the node of the first power source PV1 and the node of the control power source CONV in response to the output signal SRCON of the supply control part 902 having the enable level. For example, the current supply part 903 may operate so that a relatively small amount of current GI1 flows from the node of the first power source PV1 to the node of the control power source CONV as the level of the signal SRCON output from the supply control part 902 is relatively closer to the second specific level between the first specific level and the second specific level.

Referring to FIG. 9C, when the level of the sensing signal SENV is equal to or higher than the level of the second bias BIAS2 having the second reference level REFV2 (SENV>=BIAS2), the operation of the power supply section 807 can be seen.

First, the bias generation part 901 generates the first bias BIAS1 having the first reference level REFV1 and the second bias BIAS2 having the second reference level REFV2.

Subsequently, the supply control part 902 checks that the level of the sensing signal SENV is equal to or higher than the level of the second bias BIAS2 and outputs a signal SRCON having a disabled level according to the check result.

Subsequently, the excess control part 904 checks that the level of the sensing signal SENV is equal to or higher than the level of the second bias BIAS2 and outputs a transmission control signal DPS in a deactivated state according to the check result.

Subsequently, the first transmission part 905 may not transmit the signal SRCON output from the supply control part 902 to the current supply part 903 in response to the transmission control signal DPS, which is in the deactivated state and output from the excess control part 904.

Subsequently, the second transmission part 906 outputs the disable signal DIS in response to the transmission control signal DPS in the deactivated state and output from the excess control part 404.

In summary, in response to the fact that the level of the sensing signal SENV is equal to or higher than the level of the first bias BIAS1 having the first reference level REFV1 (SENV>=BIAS2), the disable signal DIS is transmitted to the current supply part 903 in response to the transmission control signal DPS in the deactivated state in the excess control part 904. In response to the fact that the level of the sensing signal SENV is equal to or higher than the level of the first bias BIAS1 having the first reference level REFV1 (SENV>=BIAS2), the signal SRCON having the disable level in the supply control part 902 may not be transmitted to the current supply part 903 due to the first transmission part 905.

Accordingly, the current supply part 903 is switched to a disable operation state in response to the disable signal DIS output from the second transmission part 906. That is, the current supply part 903 operates so that no current flows between the node of the first power source PV1 and the node of the control power source CONV in response to the disable signal DIS output from the second transmission part 906.

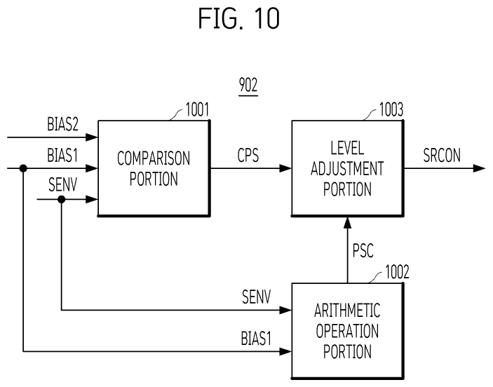

FIG. 10 is a diagram for describing a detailed configuration of the supply control part among components of the power supply section included in the master device in accordance with the second embodiment of the present disclosure.

Referring to FIG. 10, among the components of the power supply section 807 included in the master device 710 in accordance with the second embodiment of the present disclosure, the supply control part 902 includes a comparison portion 1001, an arithmetic operation portion 1002, and a level adjustment portion 1003.

First, the supply control part 902 compares the level of the sensing signal SENV with the level of the first bias BIAS1 and the level of the second bias BIAS2, respectively, and adjusts the level of the signal SRCON to be output in response to the comparison result.

When the level of the sensing signal SENV is equal to or lower than the level of the first bias BIAS1 having the first reference level REFV1, the supply control part 902 outputs a signal SRCON having a disable level.

When the level of the sensing signal SENV is between the level of the first bias BIAS1 having the first reference level REFV1 and the level of the second bias BIAS2 having the second reference level REFV2, the supply control part 902 outputs a signal SRCON having an enable level.

When the level of the sensing signal SENV is equal to or higher than the level of the second bias BIAS2 having the second reference level REFV2, the supply control part 902 outputs a signal SRCON having a disable level.

The comparison portion 1001 included in the supply control part 902 compares the level of the sensing signal SENV with the level of the first bias BIAS1 and the level of the second bias BIAS2, respectively, and generates a comparison signal CPS whose activation is determined in response to the comparison result.

According to an embodiment, the comparison portion 1001 compares the sensing signal SENV with the first bias BIAS1 and the second bias BIAS2, respectively and outputs a comparison signal CPS of an activated state when the level of the sensing signal SENV is between the first reference level REFV1 and the second reference level REFV2.

According to another embodiment, the comparison portion 1001 compares the sensing signal SENV with the first bias BIAS1 and outputs a comparison signal CPS of a deactivated state when the level of the sensing signal SENV is equal to or lower than the first reference level REFV1.

According to further another embodiment, the comparison portion 1001 compares the sensing signal SENV with the second reference level REFV2 and outputs a comparison signal CPS of a deactivated state when the level of the sensing signal SENV is equal to or higher than the second reference level REFV2.

The arithmetic operation portion 1002 included in the supply control part 902 calculates the level difference between the level of the sensing signal SENV and the first bias BIAS1 having the first reference level REFV1 and outputs a difference signal PSC.

According to an embodiment, the arithmetic operation portion 1002 outputs a difference signal PSC having a relatively large magnitude as the difference between the level of the sensing signal SENV and the first reference level REFV1 is relatively large.

The level adjustment portion 1003 included in the supply control part 902 adjusts the level of the signal SRCON to be output according to the length of an activation duration of the comparison signal CPS output from the comparison portion 1001 and the magnitude of the difference signal PSC output from the arithmetic operation portion 1002. In such a case, the level adjustment portion 1003 includes an integration circuit that substitutes the length of the activation duration of the comparison signal CPS as the level of the output signal SRCON and adjusts the level fluctuation range of the output signal SRCON according to the magnitude of the difference signal PSC.

According to an embodiment, the level adjustment portion 1003 relatively increases the level of the output signal SRCON as the length of the activation duration of the comparison signal CPS is relatively long.

According to another embodiment, the level adjustment portion 1003 relatively decreases the level of the output signal SRCON as the length of a deactivation duration of the comparison signal CPS is relatively long.

According to further another embodiment, the level adjustment portion 1003 relatively increases the level fluctuation range, that is, the increase or decrease range, of the output signal SRCON as the magnitude of the difference signal PSC is relatively large.

According to yet another embodiment, the level adjustment portion 1003 relatively decreases the level fluctuation range, that is, the increase or decrease range, of the output signal SRCON as the magnitude of the difference signal PSC is relatively small.

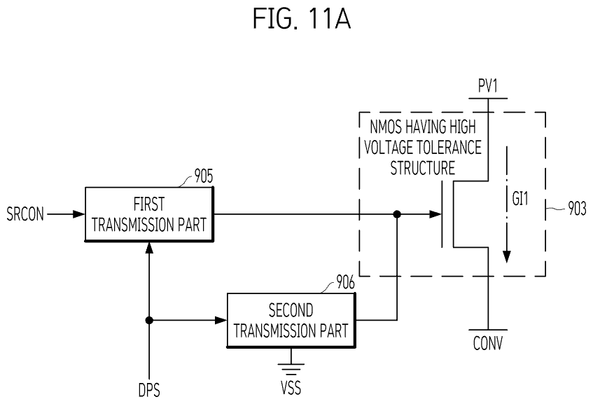

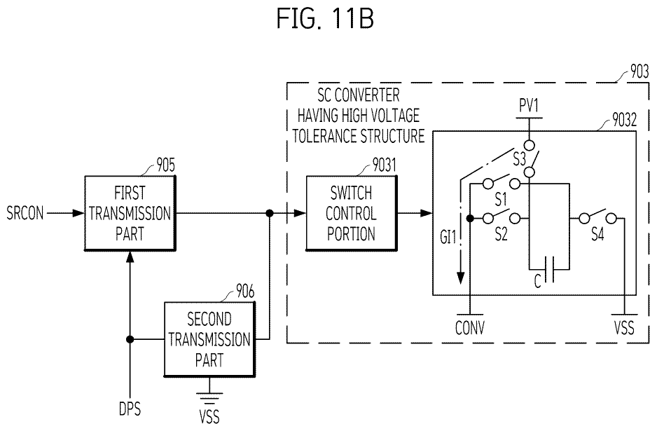

FIGS. 11A and 11B are diagrams for describing a detailed configuration of the current supply part among the components of the power supply section included in the master device in accordance with the second embodiment of the present disclosure.

First, referring to FIG. 11A, among the components of the power supply section 807 included in the master device 710 in accordance with the second embodiment of the present disclosure, the current supply part 903 includes an NMOS transistor having a high voltage tolerance structure.

Specifically, the NMOS transistor included in the current supply part 903 and having a high voltage tolerance structure adjusts the amount of current flowing from a drain thereof connected to the node of the first power source PV1 to a source thereof connected to the node of the control power source CONV, according to the level of a signal applied to a gate thereof, that is, a signal transmitted through the first transmission part 905.

The NMOS transistor having high voltage tolerance has a relatively longer physical distance between the drain and the source compared to an NMOS transistor having no high voltage tolerance. In this way, when the physical distance between the drain and the source is relatively long, an electric field is prevented from being concentrated at a specific point and destroying the transistor.

In addition, the NMOS transistor having high voltage tolerance has more high resistance drift regions inserted between the drain and the source compared to an NMOS transistor having no high voltage tolerance. In this way, when the high resistance drift region is inserted between the drain and the source, the concentration of an electric field is distributed, so that the high voltage tolerance of the transistor is increased.

In addition, the NMOS transistor having high voltage tolerance has a relatively thicker gate oxide film compared to an NMOS transistor having no high voltage tolerance. In this way, when the transistor has the thick gate oxide film, the gate oxide film is prevented from being destroyed by high voltage.

In addition, the NMOS transistor having high voltage tolerance maintains a body (Bulk) in a floating state without connecting the body to specific voltage, compared to an NMOS transistor having no high voltage tolerance. In this way, by maintaining the body in a floating state, voltage applied between the drain and the source is distributed.

In addition, the NMOS transistor having high voltage tolerance extends the length of the drain, compared to an NMOS transistor having no high voltage tolerance. In this way, by extending the length of the drain, an electric field concentration occurring when high voltage current flows, is effectively distributed.

On the other hand, as illustrated in FIG. 11A, when the current supply part 903 includes the NMOS transistor having a high voltage tolerance structure, the signal SRCON having a disable level that is transmitted through the first transmission part 905 is a signal SRCON having a ground voltage level (VSS).

Likewise, when the current supply part 903 includes the NMOS transistor having a high voltage tolerance structure as illustrated in FIG. 11A, the disable signal DIS that is transmitted through the second transmission part 906 is a signal having the ground voltage level (VSS).

Referring to FIG. 11B, among the components of the power supply section 807 included in the master device 710 in accordance with the second embodiment of the present disclosure, the current supply part 903 includes a switched-capacitor (SC) converter circuit having a high voltage tolerance structure.

Specifically, the switched-capacitor converter circuit included in the current supply part 903 and having a high voltage tolerance structure includes a switch control portion 9031 and a supply operation portion 9032.

The switch control portion 9031 generates a signal for controlling operations of the switch elements S1 to S4 included in the supply operation portion 9032 according to the level of a signal transmitted through the first transmission part 905.

The supply operation portion 9032 adjusts the amount of current flowing from the node of the first power source PV1 to the node of the control power source CONV through an operation of charging and discharging a capacitor element C connected between the node of the first power source PV1 and the node of the control power source CONV by turning on/off the switch elements S1 to S4 included therein in response to the signal output from the switch control portion 9031.

More specifically, the switch control portion 9031 supplies current from the node of the first power source PV1 to the node of the control power source CONV by alternately performing an operation of charging the capacitor element C by transmitting a signal for turning off the first, second, and fourth switch elements S1, S2, and S4 and turning on the third switch element S3 to the supply operation portion 9032 in response to the fact that the signal SRCON output from the supply control part 902 is at an enable level, and an operation of discharging the capacitor element C by transmitting a signal for turning off the first and second switch elements S1 and S2 and turning off the third and fourth switch elements S3 and S4 to the supply operation portion 9032. In such a case, the switch control portion 9031 operates so that a relatively large amount of current GI1 flows from the node of the first power source PV1 to the node of the control power source CONV by charging and discharging the capacitor element C included in the supply operation portion 9032 at a relatively higher speed as the level of the signal SRCON output from the supply control part 902 is relatively closer to the first specific level between the first specific level and the second specific level.

In addition, the switch control portion 9031 transmits a signal for turning off the first, second, and third switch elements S1 to S3 and turning on the fourth switch element S4 to the supply operation portion 9032 in response to the fact that the signal SRCON output from the supply control part 902 is at a disable level, thereby preventing the capacitor element C from being charged and discharged and at the same time, thereby allowing the node of the first power source PV1 and the node of the control power source CONV to be insulated.

On the other hand, the switch-capacitor converter circuit having high voltage tolerance has a relatively higher rated voltage than a switch-capacitor converter circuit having no high voltage tolerance because the capacitor element C included therein has a relatively thicker insulation layer.

In addition, in the switch-capacitor converter circuit having high voltage tolerance, the switch elements S1 to S4 included therein are high voltage transistors such as high voltage MOSFETs or IGBTs, compared to a switch-capacitor converter circuit having no high voltage tolerance.

In such a case, in the switch elements S1 to S4 having high voltage tolerance, a physical distance between a drain and a source of the transistor is relatively long, compared to switch elements S1 to S4 having no high voltage tolerance. In this way, when the physical distance between the drain and source of the transistor is relatively long, an electric field is prevented from being concentrated at a specific point and destroying the switch element S1 to S4.

In addition, the switch element S1 to S4 with high voltage tolerance have more high resistance drift regions inserted between the drain and source of the transistor compared to switch element S1 to S4 having no high voltage tolerance. In this way, when the high resistance drift region is inserted between the drain and source of the transistor, the concentration of an electric field is distributed, so that the high voltage tolerance of the switch element S1 to S4 is increased.

In addition, the switch elements S1 to S4 having high voltage tolerance have a relatively thicker gate oxide film of the transistor compared to switch elements S1 to S4 having no high voltage tolerance. In this way, when the transistor has a thick gate oxide film, the gate oxide film is prevented from being destroyed by high voltage.

In addition, the switch elements S1 to S4 having high voltage tolerance maintain a body (Bulk) of the transistor in a floating state without connecting the body to a specific voltage, compared to switch elements S1 to S4 having no high voltage tolerance. In this way, by maintaining the body in a floating state, voltage applied between the drain and source of the transistor is distributed.

In addition, the switch elements S1 to S4 having high voltage tolerance extend the length of the drain in the transistor compared to switch elements S1 to S4 having no high voltage tolerance. In this way, by extending the length of the drain, an electric field concentration occurring when high voltage current flows is effectively distributed.

The present invention described above is not limited by the aforementioned embodiments and the accompanying drawings, and it will be apparent to those skilled in the art to which the present disclosure pertains that various replacements, modifications, and changes may be made without departing from the technical scope of the present disclosure. Furthermore, the embodiments may be combined to form additional embodiments.

For example, the position and the type of a logic gate and a transistor shown in the aforementioned embodiments should be differentially realized according to the polarity of an inputted signal.

What is claimed is:

1. A memory system comprising:
a memory device configured to operate by receiving, from an outside, a first power source having a first voltage level; and
a controller configured to perform a control operation of controlling the memory device and to generate a control power source for the control operation by:
receiving, from an outside, a second power source, which has a second voltage level lower than the first voltage level, when a present current amount of the control power source is equal to or less than a first current amount, and
receiving both the first and second power sources when the present current amount exceeds the first current amount.

2. The memory system of claim 1, wherein:
the controller is further configured to reduce, when the present current amount is equal to or greater than a second current amount greater than the first current amount, the present current amount by stopping a M number of sub-control operations among a N number of sub-control operations being performed or scheduled to be performed,
the control operation includes the N number of sub-control operations,
N is a natural number equal to or greater than M, and
M is a natural number equal to or greater than 1.

3. The memory system of claim 2, wherein the controller reduces the present current amount to the first current amount or less by adjusting a value of M.

4. The memory system of claim 1, wherein the controller comprises:
a current sensing section configured to sense the present current amount;
a power supply section configured to adjust an amount of current supplied from a node of the first power source to a node of the control power source in response to an output signal of the current sensing section;
a power generation section configured to generate the control power source by receiving the second power source; and
a control operation section configured to perform the control operation by receiving the control power source.

5. The memory system of claim 4,
wherein the current sensing section is further configured to generate a sensing signal,
wherein the sensing signal has a first reference level or lower when the present current amount is the first current amount or greater,
wherein the sensing signal has a second reference level or higher when the present current amount is the second current amount or greater, and
wherein the sensing signal has a level between the first and second reference levels when the present current amount is between the first and second current amounts.

6. The memory system of claim 5, wherein the power supply section is further configured to supply the current from the node of the first power source to the node of the control power source only while the sensing signal has the level between the first and second reference levels.

7. The memory system of claim 6, wherein the power supply section comprises:
a bias generation part configured to generate a first bias having the first reference level and a second bias having the second reference level;
a supply control part configured to output a supply control signal, a level of which varies according to the level of the sensing signal and the first and second reference levels; and
a current supply part configured to supply, from the node of the first power source to the node of the control power source, a current having an amount corresponding to the level of the supply control signal.

8. The memory system of claim 7, wherein the supply control part comprises:
a comparison portion configured to generate a comparison signal that is activated when the level of the sensing signal is between the first and second reference levels and deactivated when the level of the sensing signal is equal to or lower than the first reference level or equal to or higher than the second reference level;
an arithmetic operation portion configured to calculate a difference between the level of the sensing signal and the first reference level; and
a level adjustment portion configured to output the supply control signal, the level of which varies according to a length of an activation duration of the comparison signal and a magnitude of an output signal of the arithmetic operation portion.

9. The memory system of claim 7, wherein the power supply section further comprises:
a first transmission part configured to transmit the supply control signal to the current supply part only in an activation duration of a transmission control signal;
a second transmission part configured to transmit a disable signal to the current supply part only in a deactivation duration of the transmission control signal, the disable signal disabling the current supply part; and
an excess control part configured to output the transmission control signal, which stays deactivated while the level of the sensing signal is equal to or higher than the second reference level and stays activated while the level of the sensing signal is lower than the second reference level.

10. The memory system of claim 7, wherein the current supply part comprises an NMOS transistor having a high voltage tolerance structure and configured to adjust, according to a level of a signal applied to a gate thereof, an amount of current flowing from a drain thereof to a source thereof, the drain being connected to the node of the first power source and the source being connected to the node of the control power source.

11. The memory system of claim 7, wherein the current supply part comprises a switch-capacitor converter having a high voltage tolerance structure and configured to adjust an amount of current flowing from the node of the first power source to the node of the control power source by controlling an operation of a switch element according to a level of an input signal to control charging and discharging of a capacitor element connected between the node of the first power source and the node of the control power source, the switch element and the capacitor element being included in the switch-capacitor converter and the input signal being input to the switch-capacitor converter.

12. An electronic apparatus comprising:
a power generation device configured to generate, by using an external power source, a first power source having a first voltage level and a second power source having a second voltage level lower than the first voltage level;
a slave device configured to perform an internal operation by receiving the first power source; and
a master device configured to perform a control operation of controlling the slave device and to generate a control power source for the control operation by:
receiving, from an outside, the second power source when a present current amount of the control power source is equal to or less than a first current amount, and
receiving both the first and second power sources when the present current amount exceeds the first current amount.

13. The electronic apparatus of claim 12, wherein:
the master device is further configured to reduce, when the present current amount is equal to or greater than a second current amount greater than the first current amount, the present current amount by stopping a M number of sub-control operations among a N number of sub-control operations being performed or scheduled to be performed,
the control operation includes the N number of sub-control operations,
N is a natural number equal to or greater than M, and
M is a natural number equal to or greater than 1.

14. The electronic apparatus of claim 13, wherein the master device reduces the present current amount to the first current amount or less by adjusting a value of M.

15. The electronic apparatus of claim 12, wherein the master device comprises:
a current sensing section configured to sense the present current amount;
a power supply section configured to adjust an amount of current supplied from a node of the first power source to a node of the control power source in response to an output signal of the current sensing section;
a power generation section configured to generate the control power source by receiving the second power source; and
a control operation section configured to perform the control operation by receiving the control power source.

16. The electronic apparatus of claim 15,
wherein the current sensing section is further configured to generate a sensing signal,
wherein the sensing signal has a first reference level or lower when the present current amount is the first current amount or greater,
wherein the sensing signal has a second reference level or higher when the present current amount is the second current amount or greater, and
wherein the sensing signal has a level between the first and second reference levels when the present current amount is between the first and second current amounts.

17. The electronic apparatus of claim 16, wherein the power supply section is further configured to supply the current from the node of the first power source to the node of the control power source only while the sensing signal has the level between the first and second reference levels.

18. The electronic apparatus of claim 17, wherein the power supply section comprises:
a bias generation part configured to generate a first bias having the first reference level and a second bias having the second reference level;
a supply control part configured to output a supply control signal, a level of which varies according to the level of the sensing signal and the first and second reference levels; and
a current supply part configured to supply, from the node of the first power source to the node of the control power source, a current having an amount corresponding to the level of the supply control signal.

19. The electronic apparatus of claim 18, wherein the supply control part comprises:
a comparison portion configured to generate a comparison signal that is activated when the level of the sensing signal is between the first and second reference levels and deactivated when the level of the sensing signal is equal to or lower than the first reference level or equal to or higher than the second reference level;
an arithmetic operation portion configured to calculate a difference between the level of the sensing signal and the first reference level; and
a level adjustment portion configured to output the supply control signal, the level of which varies according to a length of an activation duration of the comparison signal and a magnitude of an output signal of the arithmetic operation portion.

20. The electronic apparatus of claim 18, wherein the power supply section further comprises:
a first transmission part configured to transmit the supply control signal to the current supply part only in an activation duration of a transmission control signal;
a second transmission part configured to transmit a disable signal to the current supply part only in a deactivation duration of the transmission control signal, the disable signal disabling the current supply part; and
an excess control part configured to output the transmission control signal, which stays deactivated while the level of the sensing signal is equal to or higher than the second reference level and stays activated while the level of the sensing signal is lower than the second reference level.

21. The electronic apparatus of claim 18, wherein the current supply part comprises an NMOS transistor having a high voltage tolerance structure and configured to adjust, according to a level of a signal applied to a gate thereof, an amount of current flowing from a drain thereof to a source thereof, the drain being connected to the node of the first power source and the source being connected to the node of the control power source.

22. The electronic apparatus of claim 18, wherein the current supply part comprises a switch-capacitor converter having a high voltage tolerance structure and configured to adjust an amount of current flowing from the node of the first power source to the node of the control power source by controlling an operation of a switch element according to a level of an input signal to control charging and discharging of a capacitor element connected between the node of the first power source and the node of the control power source, the switch element and the capacitor element being included in the switch-capacitor converter and the input signal being input to the switch-capacitor converter.
